(19) United States
(12) Patent Application Publication
(10) Pub. No.: US 2011/0304404 A1
(43) Pub. Date: Dec. 15, 2011

(54) SIGNAL GENERATORS BASED ON SOLID-LIQUID PHASE SWITCHING

(75) Inventors: Ali Gokirmak, Mansfield, CT (US); Adam Cywar, Danbury, CT (US)

(73) Assignee: UNIVERSITY OF CONNECTICUT, Farmington, CT (US)

(21) Appl. No.: 13/032,277

(22) Filed: Feb. 22, 2011

Related U.S. Application Data
(60) Provisional application No. 61/338,536, filed on Feb. 19, 2010.

(51) Int. Cl. H03B 7/14; H01L 21/82

(52) U.S. Cl. 331/107 SL; 438/382; 257/E21.602

(57) ABSTRACT

A phase-change oscillator and pulse generator, and related methods, are provided. The phase-change oscillator and pulse generator can include a capacitor, a switching element coupled in parallel connection with the capacitor, and a resistor coupled in series with the switching element and configured to supply a bias voltage to the switching element. The switching element can have a low-resistance state in a liquid-phase and a high-resistance state in a solid phase. In addition, the switching element can have a negative thermal coefficient of resistance. In an aspect, the switching element comprises a wire of a semiconducting material having negative thermal coefficient of resistance, such semiconducting material can be doped n-type or p-type. In an aspect, the liquid-phase is a molten state of the wire and the solid-phase is a solid state of the wire. An oscillatory signal is based at least on transitioning between the molten state and the solid state.

### CROSS REFERENCE TO RELATED APPLICATIONS

This application for patent relates to and claims priority from U.S. Provisional Application Ser. No. 61/338,536, SILICON PHASE-CHANGE CIRCUIT DEVICES,” filed Feb. 19, 2010. The above-captioned provisional application is herein incorporated by this reference in its entirety.

### STATEMENT REGARDING FEDERALLY SPONSORED RESEARCH

This invention was made with government support under Grant NSF Electrical, Communications and Cyber Systems (ECCS) No. 0702307 awarded by the National Science Foundation. The government has certain rights in the invention.

### SUMMARY

In accordance with the purpose(s) of the subject disclosure, as embodied and broadly described herein, the subject disclosure, in one aspect, relates to an apparatus for providing generation of a signal based on a change in thermodynamic phase (e.g., a transition from liquid to solid or vice versa). The apparatus comprises a capacitor; a switching element coupled in parallel connection with the capacitor; the switching element having a low-resistance state in a liquid-phase and a high-resistance state in a solid phase, wherein the switching element has a negative thermal coefficient of resistance; and a resistor coupled in series with the switching element and configured to supply a bias voltage to the switching element. In an embodiment, the switching element can comprise a wire of a semiconducting material having negative thermal coefficient of resistance. In another embodiment the switching element can comprise a structure of a semiconducting material, wherein the structure has a shape suitable for placement of two terminals that serve as source and drain terminals for an applied voltage; such structure is referred to as a two-terminal structure. In addition, the switching element outputs an oscillating voltage having a frequency dependent on one or more factors comprising capacitance of the capacitor, resistance of the resistor, geometry and size of the semiconducting wire, voltage applied to the switching elements, and a contact resistance of a metal contact amongst the wire and a metal pad coupled to at least one of the resistor or the capacitor.

In another aspect, the subject disclosure relates to a device, referred to as a switching device, wherein the device comprises: a miniaturized wire of a semiconducting material (e.g., a doped elemental semiconductor) having negative temperature coefficient of resistance and having a first resistance in a solid state and a second resistance in a liquid state, wherein the first resistance is greater than a resistance of a resistor coupled to the wire, and the second resistance is less than the resistance of the resistor; and at least two contacts between the wire and at least two metal lines, wherein a contact of the at least two contacts is a metal.

In yet another aspect, the subject disclosure relates to providing a switching element having a low-resistance state in a liquid-phase and a high-resistance state in a solid phase, wherein the switching element has a negative thermal coefficient of resistance (TCR); coupling the switching element with a capacitor in a parallel connection; and coupling the switching element with a resistor in series, wherein the resistor has a resistance that is greater than a liquid-state resistance of the switching element and is less than a solid-state resistance of the switching element.

As an exemplary advantage, semiconducting phase-change signal generators is an oscillator circuit that provides AC voltage and current from a DC voltage source in a miniaturized (e.g., about 0.1 μm² to about 10 μm²) chip area with very high power density. The various signal generators described herein also can be integrated in available industrial semiconductor processes; for example, oscillator circuits, generators, or devices are compatible with complementary metal-oxide-semiconductor (CMOS) technology. In an aspect, oscillation of signal originates in repeated (e.g., periodically or otherwise reiterated) solid-liquid phase transitions in a silicon wire or other type of semiconducting wire. As another exemplary advantage, phase-change oscillations in silicon wires or other semiconductors may enable production of small-scale oscillators delivering large currents and to make small-scale pulse generators.

Additional advantages of the subject disclosure will be set forth in part in the description which follows, and in part will be apparent from such description and annexed drawings, or may be learned by practice of the subject disclosure. The advantages of the subject disclosure can be realized and attained by means of the elements and combinations particularly pointed out in the appended claims. It is to be understood that both the foregoing general description and the following detailed description are exemplary and explanatory only and are not restrictive of the various aspects, features, or advantages of the subject disclosure.

### BRIEF DESCRIPTION OF THE DRAWINGS

The accompanying drawings, which are incorporated in and constitute a part of this specification, illustrate several exemplary embodiment of the subject disclosure and together with the description, serve to explain the principles of the subject disclosure.

FIG. 1 illustrates an exemplary device in accordance with aspects of the subject disclosure.

FIGS. 2A-2D are scanning electron microscope (SEM) images of several exemplary Si-based switching elements and related contacts in accordance with aspects of the subject disclosure. Length scale is presented in FIGS. 2B-2D. In an aspect, the Si wire in FIG. 2C is single crystal and formed by etching a silicon on insulator (SOI) wafer. In another aspect, Si wires in FIGS. 2A, 2B, and 2D are nano-crystalline and formed by deposition of silicon on a thin layer of silicon dioxide on silicon.

FIG. 3 illustrates an exemplary system for measurement of properties of a phase-change oscillator embodied in a device in accordance with aspects of the subject disclosure.

FIG. 4 illustrates diagrams representative of a voltage-time (V-t) characteristic exemplary phase-change oscillator, and of a current-time characteristic for the same exemplary device.

FIGS. 5-10 illustrate various current-time (I-t) characteristics and various current-voltage characteristics for various devices, or phase-change signal generators, in accordance with aspects of the subject disclosure.

FIGS. 11A-11B illustrate (i) exemplary current-time (I-t) and voltage-time (V-t) characteristics and (b) exemplary current-voltage (I-V) characteristics, respectively, of an exemplary device in accordance with aspects of the subject disclosure.

FIG. 12 illustrates current-time (I-t) and voltage-time (V-t) characteristics of an exemplary device in accordance with aspects of the subject disclosure.

FIGS. 13A-13C SEM images of an exemplary Si-based switching element having a constriction in accordance with aspects of the subject disclosure. Images in FIGS. 13B-13C are detailed views of the structure defect. Length scale is presented in FIGS. 2B-2D.

FIGS. 14A-14C and FIG. 15 illustrate various exemplary current-time (I-t) characteristics for various exemplary devices, or phase-change signal generators, in accordance with aspects of the subject disclosure.

FIG. 16 illustrates results of fast Fourier transform analysis of I-t data related to various devices, or phase-change generators of signal, in accordance with aspects of the subject disclosure.

FIG. 17 represents a model of a switching element in accordance with aspects of the subject disclosure.

FIGS. 18A-18B present results of simulations of a device, or a signal generator based on solid-liquid phase swtiching, for switching elements modeled as illustrated in FIG. 17 in accordance with aspects of the subject disclosure.

FIG. 19 is a diagram that summarizes trends of predicted oscillation frequency for various devices in accordance with aspects described herein.

FIG. 20 presents a resistance-capacitance map that summarizes results of predictions associated with phase-change oscillators for the model switching element of FIG. 17.

FIG. 21 illustrates an exemplary system that can be employed to treat wires of semiconducting materials that can embody a switching element in accordance with an aspect described herein.

FIGS. 22-25 are SEM images of several exemplary Si-based switching elements and related contacts in accordance with aspects of the subject disclosure.

FIG. 26 illustrates various current-time (I-t) characteristics for various devices, or signal generators based on solid-liquid phase switching, in accordance with aspects of the subject disclosure.

FIG. 27 illustrates estimated resistance of a Si wire in a signal generator based on solid-liquid phase switching in accordance with aspects herein.

FIG. 28 illustrates estimated resistivity as a function of width in a device, or signal generator based on solid-liquid phase switching, in accordance with aspects herein.

FIG. 29 illustrates an exemplary method for generating signal based on solid-liquid phase switching according to aspects of the subject disclosure.

### DETAILED DESCRIPTION

The subject disclosure may be understood more readily by reference to the following detailed description of exemplary embodiments of the subject disclosure and the Examples included therein and to the Figures and their previous and following description.

Before the present compounds, compositions, articles, devices, and/or methods are disclosed and described, it is to be understood that the subject disclosure is not limited to specific synthetic methods, specific materials and material combinations, or to particular shapes or morphologies, as such may, of course, vary. It is also to be understood that the terminology used herein is for the purpose of describing particular embodiments only and is not intended to be limiting.

As used in the specification and the appended claims, the singular forms “a,” “an” and “the” include plural referents unless the context clearly dictates otherwise. Thus, for example, reference to “a metal contact” includes mixtures of contacts made of different metals, reference to “a metal/semiconductor interface” includes mixtures of two or more metal/semiconductor interfaces, reference to “a metal/insulator interface” refers to a single metal/insulator interface or to mixtures of two or more such interfaces, and the like.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

In the subject disclosure and in the claims which follow, reference will be made to a number of terms which shall be defined to have the following meanings: “Optional” or “optionally” means that the subsequently described event or circumstance may or may not occur, and that the description includes instances where said event or circumstance occurs and instances where it does not.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Throughout the description and claims of the subject specification, the word “comprise” and variations of the word, such as “comprising” and “comprises,” means “including but not limited to,” and is not intended to exclude, for example, other additives, components, integers or steps. “Exemplary” means “an example of and is not intended to convey an indication of a preferred or ideal embodiment. “Such as” is not used in a restrictive sense, but for explanatory purposes.

Reference will now be made in detail to several exemplary embodiments of a phase-change oscillator and pulse generator in accordance with aspects of the subject disclosure. Wherever possible, the same reference numbers are used throughout the drawings to refer to the same or like parts.

As discussed in greater detail below, a phase-change oscillator and a phase-change pulse generator are provided. Such oscillator and generator operate based at least in part on switching from a solid-state phase to a liquid-state phase; collectively, the phase-change oscillator and the phase-change pulse generator are referred to as signal generators based on solid-liquid phase switching. The phase-change oscillator and pulse generator can include a capacitor, a switching element coupled in parallel connection with the capacitor, and a resistor coupled in series with the switching element and configured to supply a bias voltage to the switching element. The switching element can have a low-resistance state in a liquid-phase and a high-resistance state in a solid phase. In addition, the switching element can have a negative thermal coefficient of resistance. In an aspect, the switching element comprises a wire of a semiconducting material having negative thermal coefficient of resistance, such semiconducting material can be doped n-type or p-type. In an aspect, the liquid-phase is a molten state of the wire and the solid-phase is a solid state of the wire. Oscillatory signal is based at least on switching from the molten state to the solid state.

In certain embodiments, the switching element that is part of a phase-change oscillator or pulse generator can be embodied in a highly-doped nanocrystalline Si microwire (e.g., a wire with dimension of about 2 μm×about 200 nm). Such Si microwire is biased with DC voltage (e.g., about 20 V) through a load resistor which is coupled in series with the Si microwire. In addition, a coaxial cable measuring voltage between the Si microwire and load resistor can provide a capacitance in parallel with the microwire, such capacitance can enable at least in part relaxation oscillations of signal (current signal, voltage signal, current, voltage, etc.). In an aspect, the microwire melts and re-solidifies repeatedly, for example, at a frequency of about 1 MHz, which results in high amplitude oscillations in current (e.g., from about 2 mA to about 20 mA), AC voltage at the node between the load resistor and Si microwire (AV voltage ranges from about 9 V to about 17 V). In additional or alternative embodiments, a miniaturized Si wire (e.g., a wire with dimension of about 2 μm×about 200 nm) can repeatedly (e.g., periodically or aperiodically) disconnect in response to melting, and reconnect in response to re-solidification due to a specific structural feature (e.g., a constriction) in the miniaturized Si wire's geometry and the about 5% volume change in Si during solid-liquid phase transitions. Such structural feature (e.g., the constriction) enables connection (e.g., ON connectivity) and disconnection (OFF connectivity) at the position within the wire wherein the structural feature is located. Variations in ON/OFF connectivity of the miniaturized Si wire can result in generation of signal pulses at a rate of at least 9 MHz, with amplitudes of about 7 mA; other amplitudes also can be realized. Certain exemplary signal pulses can have a width of about 13 ns and rise time and fall time of about or less than about 350 ps. While various aspect, features, and advantages of the subject disclosure are illustrated with reference to a wire of a semiconducting material, it is noted that such aspects, features, and advantages also can be accomplished in most any structure with a shape suitable for being contacted with two terminals which can serve as a source terminal and a drain terminal for an applied voltage; such structure is referred to as two-terminal structure in the subject disclosure.

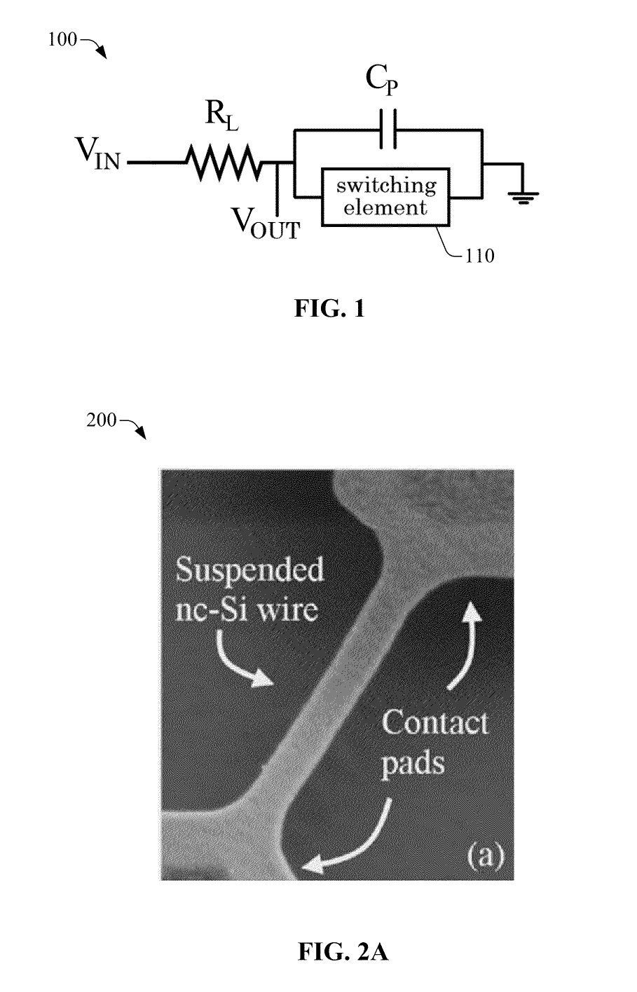

Referring to the drawings, FIG. 1 illustrates an exemplary device 100 in accordance with aspects of the subject disclosure. Devices comprising a switching element are referred to as switching devices. The exemplary device comprises a switching element 110 that is functionally coupled in parallel with a capacitor C_{P}, and is biased with an input voltage V_{IN} through a load resistor R_{L}. Exemplary device 100 and the various devices described herein also can be integrated in available industrial semiconductor processes; for example, oscillator circuits, generators, or devices are compatible with complementary metal-oxide-semiconductor (CMOS) technology. Biasing the switching element 110 through the load resistor R_{L} with the input voltage V_{IN} is referred to herein as “stressing” the switching element. Specific features of switching element 110, and magnitude of capacitor C_{P} and load resistor R_{L} are design parameters and thus can characterize, at least in part, the device 100. In certain embodiments, capacitor C_{P} comprises capacitance from coaxial cables that can enable probing the switching element can embody the capacitance of the capacitor; the capacitance from such coaxial cables commonly is a parasitic capacitance and can be about 240 pF.

Switching element 110 can have hysteretic behavior in the resistance switching of these elements. Such behavior allows the capacitor C_{P} to charge when the device is in high-resistance state and discharge when the device switches to low-resistance state in repeated biasing cycles. Such charge-discharge cycle can result in relaxation oscillations. In certain embodiments, switching element 110 is a wire of a semiconducting material that switches repeatedly amongst a solid phase and a liquid phase. The semiconducting material can be an intrinsic semiconductor or a doped semiconductor (p-doped or n-doped). In an aspect, the semiconducting material is an elemental semiconductor such as Si or Ge; the elemental semiconductor can be pure, or intrinsic, or include impurities, e.g., p-type doping, n-type doping. In another aspect, the semiconducting material is a III-V compound semiconductor (GaAs, InAs, InP, etc.) or a II-VI compound semiconductor (CdSe, CdS, ZnSe, ZnS, etc.). In yet another aspect, the semiconducting material is a semiconducting alloy such as CuGaSe or CuInSe. In still another aspect, the semiconducting material can be semiconducting oxide such as zinc oxide, magnesium oxide, or the like. In additional or alternative embodiments, the material of the wire can be an insulator such as tungsten oxide, silicon oxide, aluminum oxide, or the like. The switching material can have a negative thermal coefficient of resistance over at least a portion of the range of temperatures from room temperature to melting temperature of the semiconductor material. For example, for p-doped Si with a dopant concentration of the order of 10¹⁹ cm⁻³, TCR has positive values for lower temperatures, switching to negative values for higher temperature ranges.

In the solid phase, a wire of semiconducting material that embodies, in part, switching element 110 can have at least one characteristic dimension, wherein a characteristic dimension represent a size of the wire. In an embodiment, the wire can have two characteristic dimensions: a width (W) which can represent a size of section of the wire, and a length (L). The width can range from about 50 nm to about 700 nm, and the length can range from about 0.1 μm to about 5.5 μm.

Wires of semiconducting materials can be obtained through various processes. For example, wires can be fabricated from a thin film of highly doped nanocrystalline Si with room temperature resistivity of (12.0±2.9) mΩcm (p-type) or (35.6±0.5) mΩcm (n-type). Various materials, semiconducting (e.g., Si) or otherwise, can be employed as a substrate for such thin films. In an aspect, Si films are deposited in a low pressure chemical vapor deposition system at 560° C. with high-level in situ boron doping. In another aspect, the low pressure chemical vapor deposition of Si films is accomplished at 600° C. with phosphorus doping on Si substrates with thermally grown oxide. Photolithography and reactive ion etching are used to define the wires with specific widths and lengths (L). As-fabricated wires have a mixed nanocrystalline/amorphous phase with a negative temperature coefficient of resistance (TCR). Contact resistance (R_{C}) between a probe and Si wire ranges from about 2.5 kΩ to about 5 kΩ; R_{C} can originate from the probes contacting the metal pads, the metal lines, the metal lines contacting Si pads leading to the wire, and the Si pads. It is noted that the melting temperature of bulk Si (T_{melt Si}) is approximately 1415° C., and the resistivity of liquid Si is 7×10⁻⁵ Ωcm.

In the alternative, silicon wires can be fabricated on thin films of nanocrystalline silicon (nc-Si). Both n-type and p-type films were deposited on thermally oxidized single crystal silicon substrates in a low pressure chemical vapor deposition system with high-level in situ doping (about 5×10²⁰ cm⁻³) of phosphorus at 580° C. and boron at 560° C. It is noted that other semiconductor substrates. Wires are defined using photolithography and reactive ion etching. Wires have design widths (W_{d}) ranging from 100 to 600 nm with 10 nm increments and lengths (L) from 0.5 to 5.5 μm with 0.5 μm increments. In certain embodiments, n-type nc-Si wires, anchored between large-area Si contact pads, suspended by etching the underlying SiO₂ using buffered oxide etch can be fabricated and employed within phase-change oscillators described herein.

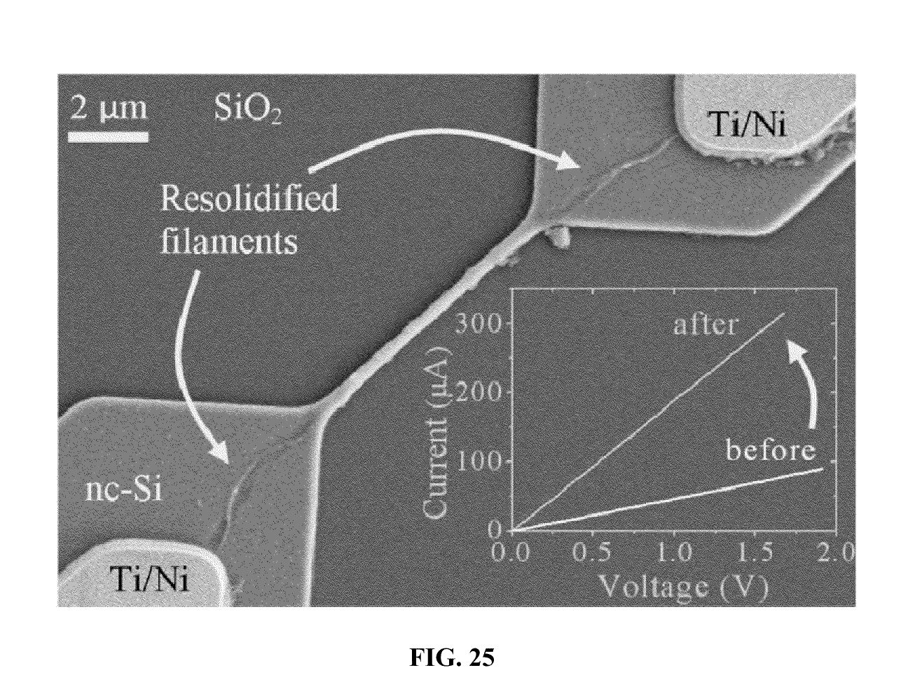

In additional or alternative embodiments, p-type nc-Si wires on SiO₂, on which 300 nm thick metal contacts (Ti/Ni) were formed using photolithography, metal evaporation and lift-off processes (see, e.g., FIG. 25). In an aspect, film thicknesses (t) are measured as 80 nm for n-type and 120 nm for p-type films using optical interferometry.

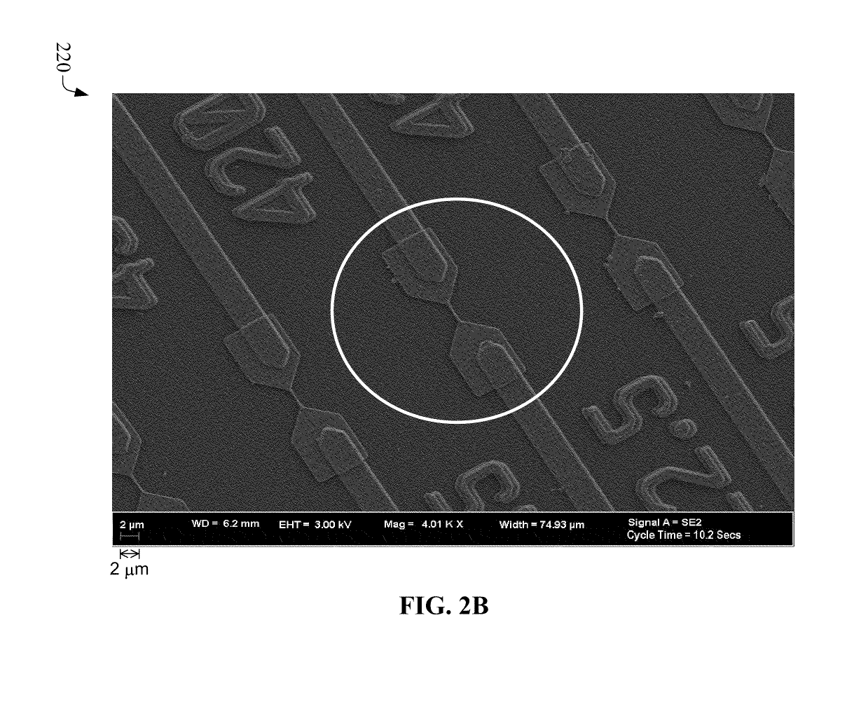

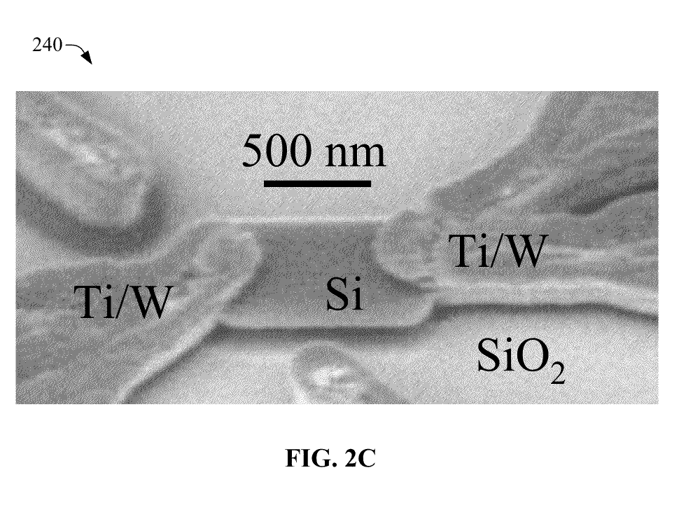

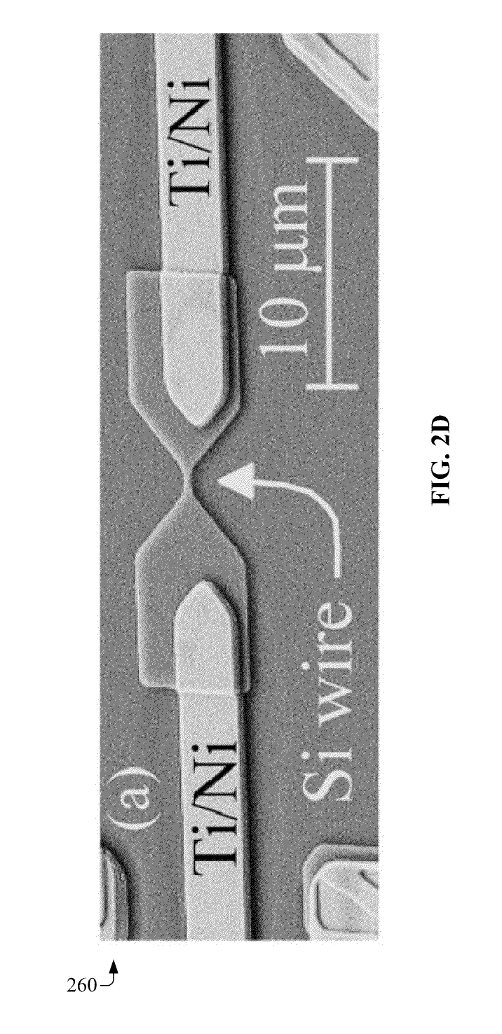

To form a switching device (e.g., device 100) in accordance with aspects of the subject disclosure, a wire of semiconducting material is contacted with contact pads and metal lines; see, e.g., exemplary device 200 in FIG. 2A, and exemplary devices 220 in FIG. 2B. The metal lines and contact pads can be formed via photolithography, metal evaporation, and various lift-off processes. Most any or any metal(s) can be employed to form such contact pads and metal lines. In an embodiment, TiW metal lines and contact pads can be formed; see, e.g., image of exemplary device 240 in FIG. 2C. In another embodiment, a wire of semiconducting material can be contacted with Ti/Ni metal line and contact pads; see, e.g., image of exemplary device 260 in FIG. 2D. In yet another embodiment, a wire of semiconducting material can be contacted with Ti/Al metal lines and contact pads. In certain embodiments, the wire of semiconducting material can be suspended between the contact pads, as illustrated in FIG. 2A, wherein a wire of crystalline Si or nano-crystalline Si embodies at least part of the switching element. In additional or alternative embodiments, the wire of semiconducting material can be fabricated on top of an insulator and thus not be suspended; such wire is illustrated in FIG. 2C. In one or more embodiments, suspended or non-suspended wires can be passivated with a material different from the semiconducting material of the wire—structure presented in FIG. 2A is non-passivated; structure presented in FIG. 2C is a non-suspended passivated wire. In the alternative, the suspended or non-suspended wires can be non-passivated.

In an aspect, the Si wire in FIG. 2C is single crystal and formed by etching a silicon on insulator (SOI) wafer. In another aspect, Si wires in FIGS. 2A, 2B, and 2D are nano-crystalline and formed by deposition of silicon on a thin layer of silicon dioxide on silicon. It should be appreciated that other semiconductor-on-insulator structures are contemplated in the subject disclosure.

In response to certain electric currents (e.g., a current greater than about 20 MA/cm²) being forced through a wire of semiconducting material with negative TCR, the wire can self-heat and melt as a result of self-heating. The self-heating in conjunction with the wire's negative TCR can result in positive feedback. In an aspect, wire resistance (R_{W}) decreases as Joule heating increases, causing an increase in dissipated power leading to a thermal runaway and melting. A wire which melts and re-solidifies typically has about 5 to about 10 times lower resistance after annealing (R_{WF}) than its as-fabricated resistance (R_{WO}).

In an embodiment in which a wire of semiconducting material with negative TCR is connected in series with a load resistor (R_{L}), power delivered to the wire (P_{W}) is maximized when R_{L}=R_{W}. Accordingly, in a scenario, a value for R_{L} can be selected to be the expected value of R_{WF}. When sufficient DC voltage V_{IN} is applied across such series connection, the wire (e.g., a silicon wire) can begin self-heating and thus R_{W} can begin decreasing while P_{wire} can begin increasing. When R_{W} decreases to a value approximately equal to R_{L}, P_{wire} is maximized and the wire can melt. In an aspect, the resistance of a molten wire ranges from about 10Ω to about 200Ω, thus R_{W}<<R_{L}, and P_{W} is insuffic to keep the wire molten. Therefore, in an aspect, the wire is able to start solidifying and thus R_{W} can increase, approaching R_{WF}. Since R_{WF}≈R_{L}, R_{W}, or P_{wire} is maximized upon or substantially upon the wire solidifies, resulting in melting again.

In general, in scenarios in which R_{W liquid}<R_{L}<R_{WF}, dissipated power P_{wire} can be sufficient for melting an as-fabricated wire and an annealead (e.g., critically annealed) wire under the same or substantially the same bias condition (e.g., value of applied V_{IN}). Accordingly, in such scenarios, an instability can be achieved in the devices disclosed herein because P_{wire} cannot be sufficient to keep in a liquid phase a wire that is part of the switching. As illustrated in device 110, devices described in the subject disclosure also can include a capacitor (e.g., capacitor C_{P}) functionally coupled (e.g., functionally connected). Capacitance of the capacitor in combination with the foregoing instability can result in an operation condition of the exemplary device 110 that exhibits relaxation oscillations for certain bias DC voltages (e.g., V_{IN}). Accordingly, device 110 is referred to as a phase-change oscillator or a phase-change signal generator.

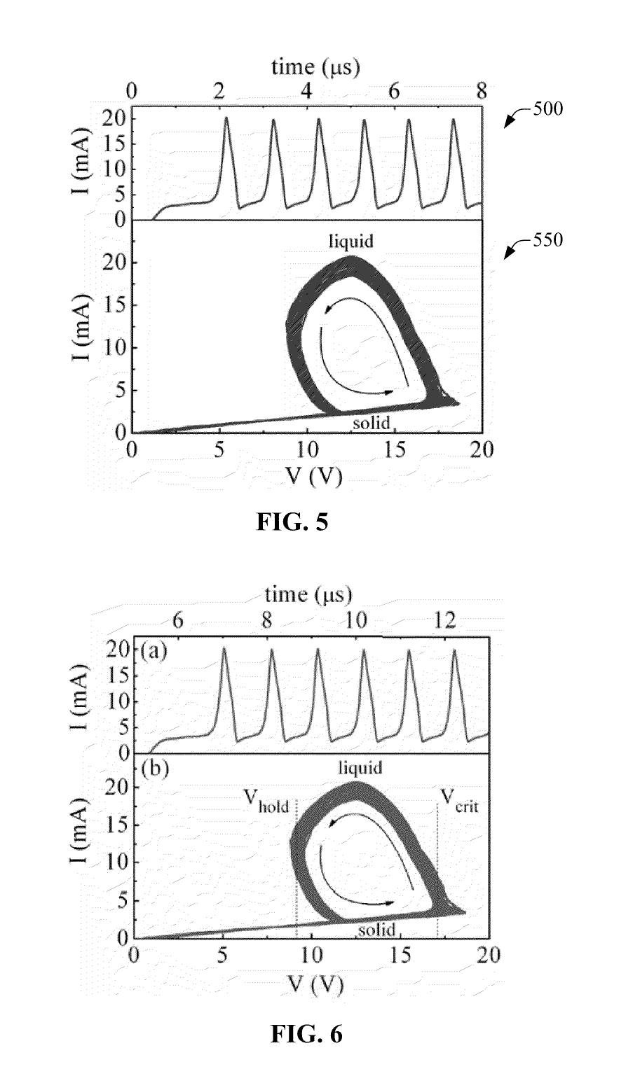

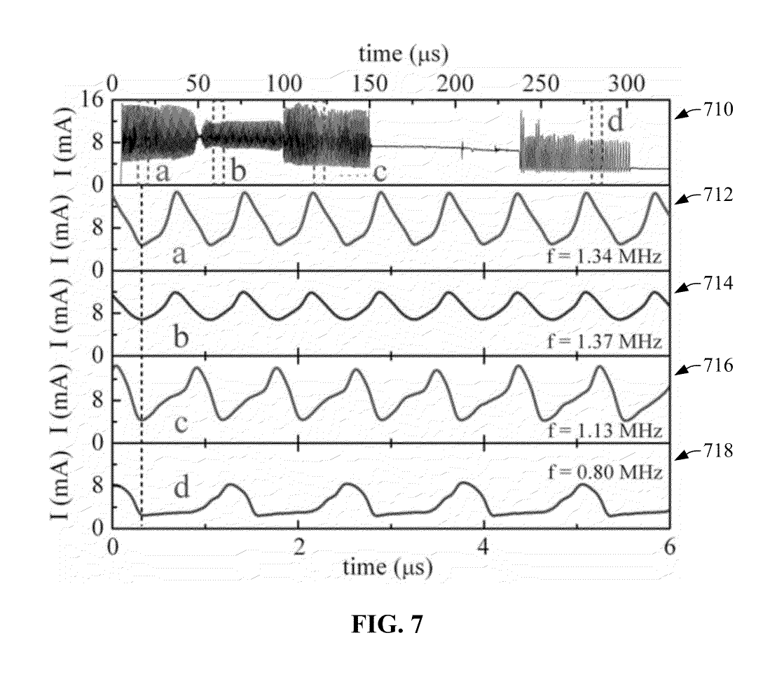

In one or more devices, maximum and minimum resistances of a wire (e.g., wire illustrated in FIG. 2B) during such relaxation oscillations indicate that the wire can oscillate between a completely solid or substantially completely solid and a completely liquid or substantially completely liquid state (see, e.g., FIG. 5). In another aspect, values of resistances indicate that wire can transition between different states with different liquid-solid ratios along the length of the wire (see, e.g., FIG. 7). Amplitude and frequency of a relaxation oscillation are generally determined, at least in part, by R_{L}, R_{W}.

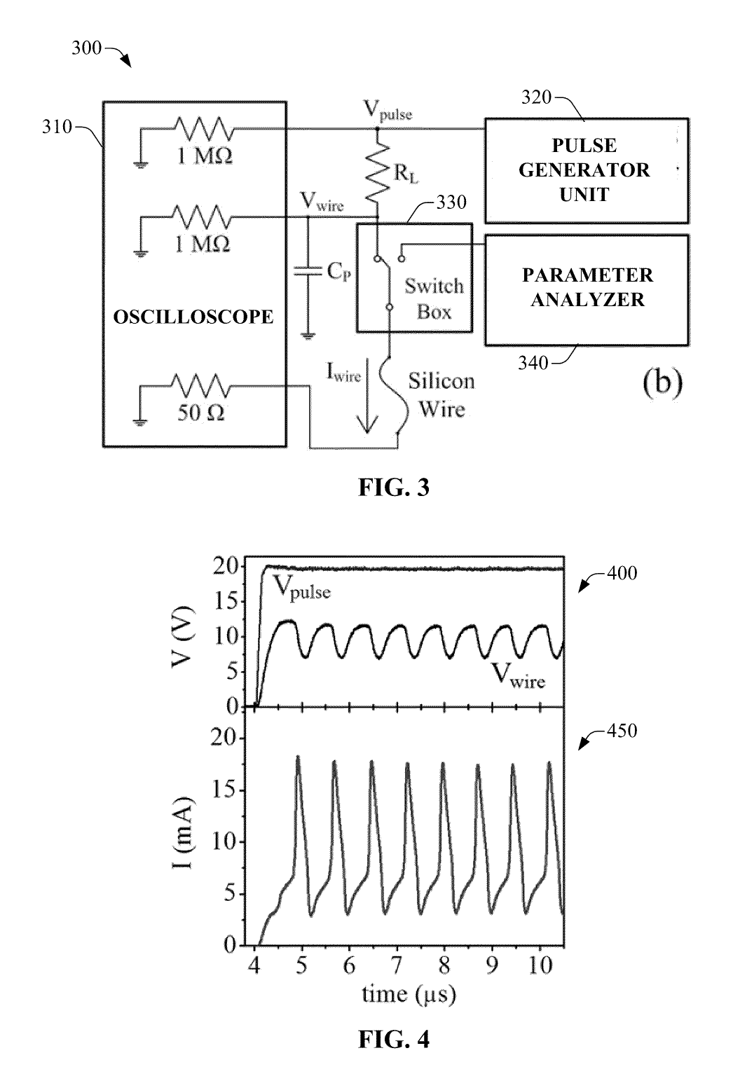

FIG. 3 illustrates an exemplary system 300 for measurement of properties of a phase-change oscillator embodied in devices (e.g., exemplary device 100) in accordance with aspects of the subject disclosure. Exemplary system 300 comprises a parameter analyzer 340 that can control a pulse generator unit (PGU) 320, a switch box 330, and an oscilloscope 310. A probed device comprises a load resistor R_{L} that is coupled (e.g., directly connected) to the switch box 330 and the PGU 320 in a manner that allows measurements of DC current-voltage (I-V) characteristics of the wire without R_{L} being part of the device. In an aspect, oscilloscope 320 can be a multi-channel oscilloscope. A first oscilloscope channel with 1 MΩ (∥13 pF) input impedance can monitor the supply voltage, or bias voltage V_{IN}, which is labeled Vₚᵤₗₛₑ in FIG. 3, and a second oscilloscope channel with 1 MΩ (∥13 pF) input impedance can monitor the voltage across a wire that is part of the probed device; the voltage across the wire is labeled V_{wire} in FIG. 2. A third oscilloscope channel collects current that circulates through the wire (labeled I_{wire} in FIG. 3). Oscilloscope 320 and parameter analyzer 340 can be controlled by a computing device (not shown), such as a computer, a programmable logic controller (PLC), a mobile device, or the like. Signal output (e.g., V_{OUT} in FIG. 1) from the probed device to the oscilloscope 32 is transmitted through coaxial cables; in an aspect, approximately two meters of coaxial cable with about 100 pF/m of capacitance and about 0.5 μH/m of inductance can be used in exemplary system 300 to transmit signal (e.g., voltage signal) to the oscilloscope 310.

FIG. 4 illustrates a diagram 400 representative of a voltage-time characteristic for an exemplary device (or exemplary phase-change oscillator), and a diagram 450 representative of a current-time characteristic for the same exemplary device. In an aspect, the exemplary device comprises a switching element including a wire having a width of about 400 nm, a thickness of about 100 nm, and a length of about 2 μm. After an initial ramp-up interval, Vₚᵤₗₛₑ achieves a value of about 19 V and remains nearly stationary (e.g., present small fluctuations); in response, voltage V_{wire} across the wire initially increases up to a first value of nearly 12 V and oscillates amongst the first value (e.g., maximum value) and a second value (e.g., minimum value). It should be appreciated that transition from the first value to the second value occurs in a characteristic time that is amongst the first value and the second value is shorter than the characteristic time to transition from the second value to the first value. Current I_{wire} increases and decreases in phase with V_{wire}.

FIG. 5 illustrates a diagram 500 representative of a current-time (I-t) characteristic for current circulating through an additional or alternative exemplary device (or exemplary phase-change oscillator), and a diagram 550 representative of a current-voltage (I-V) characteristic for the same exemplary device. In an aspect, the exemplary device comprises a suspended, p-type Si wire with a length of about 2.5 μm, a width of about 220 nm, and a thickness of about 120 nm. In another aspect, the exemplary device comprises a load resistor R_{L} of about 1.18 kΩ. In diagram 500, current remains at about 2.5 mA for nearly 1.9 μs, subsequently the current presents oscillations responsive to oscillations in phase state of the wire that embodies the switching element. Current-voltage (I-V) characteristic in diagram 550 indicates that the switching device transitions reversibly and, to some extent, hysteretically, from a solid phase to a liquid phase, wherein resistance in the liquid phase is less than resistance in the solid phase. Maximum and minimum resistances of the wire that embodies the switching element in the exemplary device indicate that the wire can oscillate between a completely solid or substantially completely solid state and a completely liquid or substantially completely liquid state during phase-state relaxation oscillations.

FIG. 6 illustrates a diagram 600 representative of a current-time (I-t) characteristic for current circulating through an additional or alternative exemplary device (or exemplary phase-change oscillator), and a diagram 650 representative of a current-voltage (I-V) characteristic for the same exemplary device. The subject exemplary device is embodied in a critically annealed p-type wire with L of about 2.5 μm, of about 220 nm, and thickness of nearly 120 nm. Such device is stressed through a load resistor R_{L}=1.18 kΩ via application of a bias voltage with a train of pulses (e.g., a waveform), each pulse having an amplitude (Vₚᵤₗₛₑ) of about 23 V and a duration of about 320 μs. The subject exemplary device is a phase-change oscillator with a frequency of about 870 kHz. As in FIG. 5, the exemplary device linked to data in diagram 650 has maximum and minimum resistances of the wire that embodies the exemplary device indicate that the wire can oscillate between a completely solid or substantially completely solid and a completely liquid or substantially completely liquid state during phase-state relaxation oscillations. As illustrated, the low-resistance state in the switching element embodied in the wire remains until voltage across a device drops below a lower threshold voltage value V_{hold}—an estimated value of V_{hold} for the subject device is illustrated in FIG. 6. The threshold value V_{crit} represents an estimated value of a voltage at which the exemplary device instantaneously switches to a low-resistance state (e.g., R_{W}=R_{W liquid}).

FIG. 7 presents various panels 710-718 conveying I-t characteristics for the exemplary device of FIG. 6. Top panel presents oscillations of current I_{wire} over the time scale of a bias pulse. The bias pulse has an amplitude (Vₚᵤₗₛₑ) of about 21 V and a duration of nearly 320 μs. Four different regions are distinguishable, each region having a characteristic response to the applied bias voltage pulse. Panels labeled a-d are representative of I-t characteristics of the four zones that can be observed in the top panel. (Curves are shifted and aligned for clarity.) Each region distinguishable in the top panel transitions has an oscillation frequency specific to that I-t region, wherein the frequency is constant or substantially constant within such region. For example, region a (labeled “a” in panel 710 in the drawing) has an oscillation frequency of about 1.34 MHz (see panel 712); region b (labeled “b” in panel 710) has an oscillation frequency of about 1.37 MHz (see panel 714); region c has an oscillation frequency of about 1.13 MHz (see panel 716); and region d has an oscillation of about 0.80 MHz (see panel 718). Accordingly, phase-change oscillators related to data in FIG. 7 have oscillation frequencies of the order of 1 MHz.

Values of resistances defined by data related to I-t data indicate that the wire that embodies the subject exemplary device can transition between different states with different liquid-solid ratios along the length of the wire. Amplitude and frequency of a relaxation oscillation are generally determined, at least in part, by R_{L}, R_{W}in solid state (R_{W solid}), Vₚᵤₗₛₑ, C_{P}, and time scale of melting and re-solidification.

Every time a wire melts and re-solidifies there is an adjustment (e.g., a small change) in solid-state wire resistance. Each oscillatory period consists of one cycle of melting and re-solidification and oscillation amplitude is slightly different in each period. The system is observed to abruptly lose or gain resonance as R_{W solid} (resistance is solid state) changes over a typical time scale of about 50 μs for the exemplary device and bias pulse(s) associated with data presented in FIG. 7. In this particular case, R_{W} increases by approximately three times (to about 50% of R_{W0}).

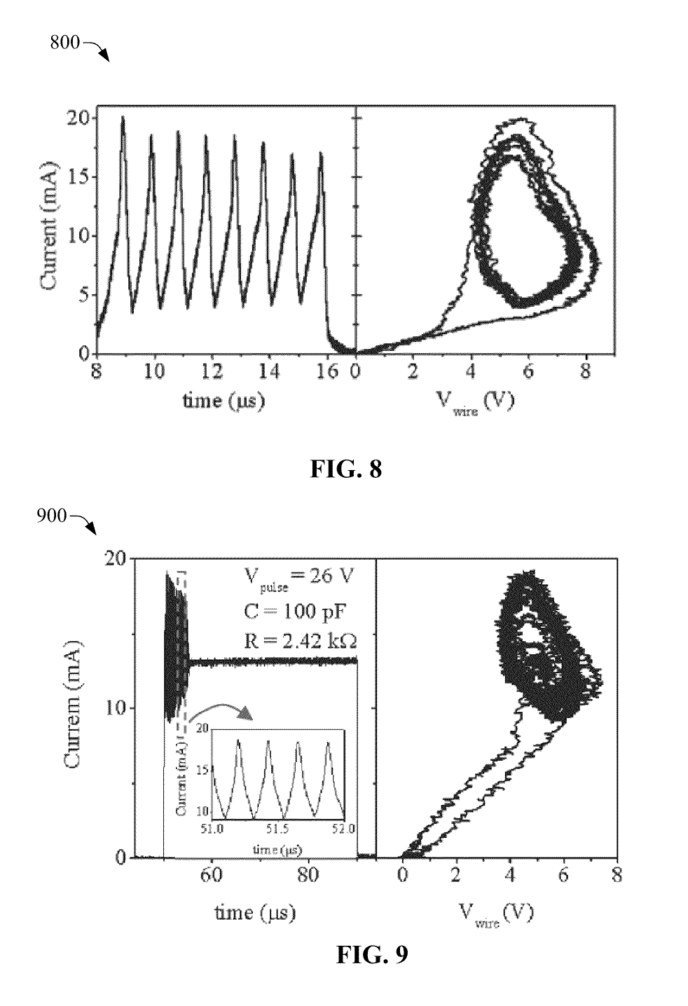

FIG. 8 is a diagram 800 that displays current-time (I-t) characteristic in left panel and current-voltage characteristics during stress, or load, for an exemplary device in accordance with aspects described herein. In an aspect, the exemplary device has a switching element embodied in a suspended, p-type Si wire with a length of about 1 μm. In further aspect, the exemplary device includes a load resistor R_{L} of about 1.18 kΩ; R_{L} enables stressing the switching element (e.g., 110) with a bias pulse with an amplitude Vₚᵤₗₛₑ of about 18 V. In a yet further aspect, the switching element is connected in parallel with a capacitor C_{P} with capacitance of about 500 pF.

FIG. 9 is a diagram 900 that displays I-t characteristic in left panel and I-V characteristics during stress for an exemplary device in accordance with aspects described herein. In an aspect, the exemplary device has a switching element embodied in a non-suspended, p-type Si wire on oxide, the wire having a length of about 4 μm. In further aspect, the exemplary device includes a load resistor R_{L} of about 2.42 kΩ; R_{L} enables stressing the switching element (e.g., 110) with a bias pulse with an amplitude Vₚᵤₗₛₑ of about 26 V. In a yet further aspect, the switching element is connected in parallel with a capacitor C_{P} with capacitance of about 100 pF. As illustrated in left panel of diagram 900, the subject exemplary device is a phase-change oscillator that is stable over an interval of about 30 μs. Even though the oscillation is not stable, it should be appreciated that at least some of the design parameters of the device (e.g., R_{L}, C_{P}, and wire length, width, and thickness) enable a frequency of phase-change oscillation of nearly 4.4 MHz. Such instability also is revealed by the I-V curves in the right panel of diagram 900: As the exemplary device becomes unstable, the hysteresis loop associated with a bi-stable wire is reduced in size, resembling absence of hysteresis, which represents a non-switching element.

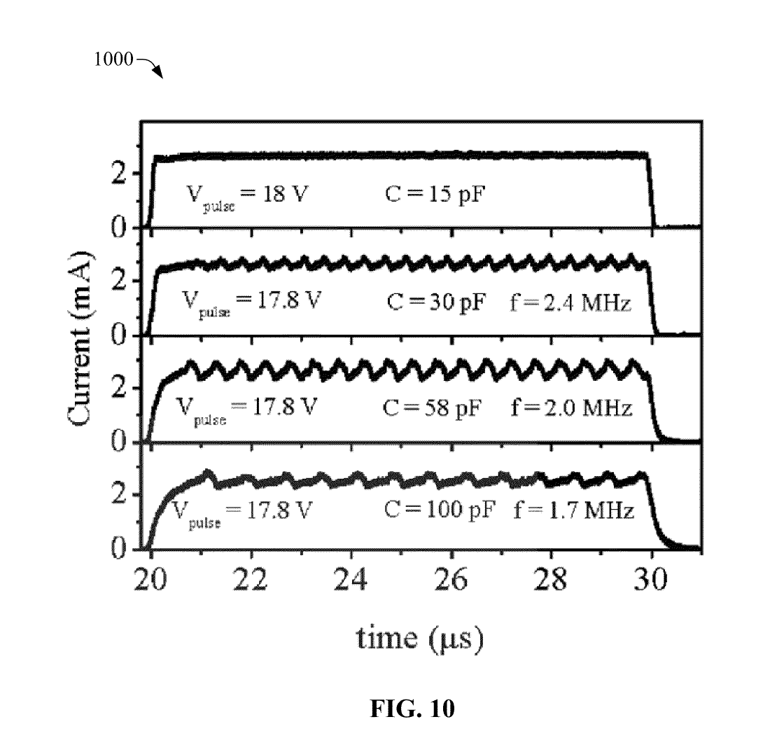

FIG. 10 is a diagram 1000 of current-time characteristics for four exemplary devices in accordance with aspects of the subject disclosure. The switching element (e.g., 110) in each of the exemplary devices is the same or substantially the same, and is embodied in a suspended, intrinsic Si wire. In addition, each of such devices comprises a load resistor R_{L} of about 3 kΩ In an aspect, the four exemplary devices have different capacitors C_{P}: a first exemplary device has C_{P} of about 15 pF; a second device has C_{P} of about 30 pF; a third device has a C_{P} of about 58 pF; and a fourth device has a C_{P} of about 100 pF. Current-time characteristics of such device are presented in diagram 900 and identified with respective values of capacitance of capacitor C_{P}. In an aspect, the first device is not a phase-change oscillator. In another aspect, the second device, the third device, and the fourth device are phase-change oscillators with an oscillation frequency of about 2.4 MHz, about 2.0 MHz, and about 1.7 MHz, respectively.

In an aspect, the oscillation frequency of a device as disclosed herein can be limited by charging rate and discharging rate of the capacitor C_{P} that is part of the device. In an aspect, the oscillation frequency is determined, at least in part, by the time constant τ₀=(R_{wire}∥R_{L})C, where R_{wire} is the resistance of a wire (e.g., Si wire) that embodies the switching element and related contact pads, the wire switching between high-resistance and low-resistance states, R_{wire}∥R_{L} is the load resistance in parallel with the wire resistance, and C is the capacitance of capacitor C_{P}. In an aspect, the oscillation frequency is the reciprocal of a characteristic time that spans several time constants. Hence, higher frequency oscillations are expected for lower total resistance R_{wire}∥R_{L} and/or capacitance C_{P}. Discharge time is dominated by R_{Si} in liquid phase, which is about 30 times smaller compared to its solid phase value and discharge is typically faster than charge up. It is noted that total resistance in solid phase and device capacitance are design parameters that can be adjusted in order to achieve a satisfactory (optimal for an application, nearly optimal for an application, predetermined based on technical specification(s), etc.) oscillation frequency for a phase-change oscillator embodied in the device.

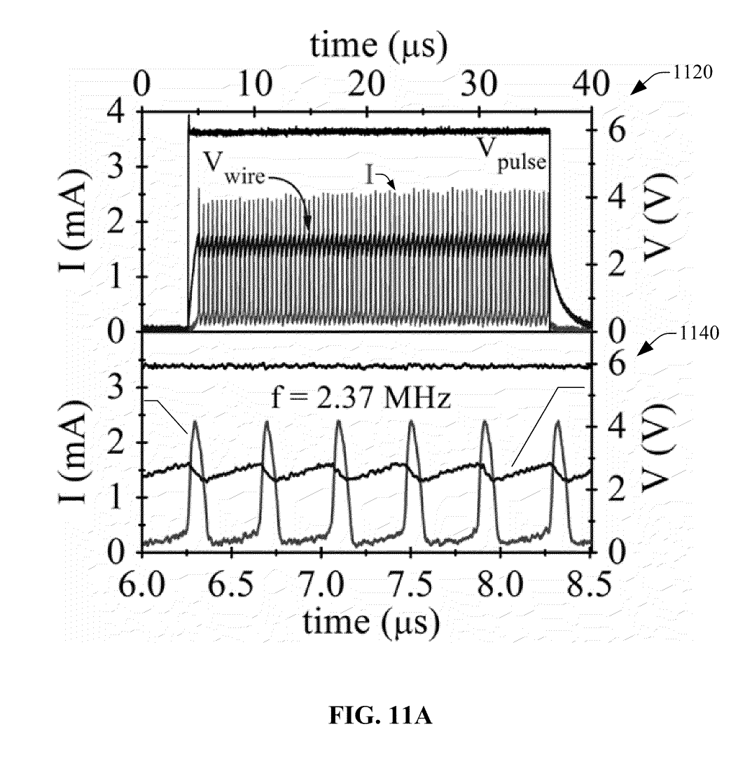

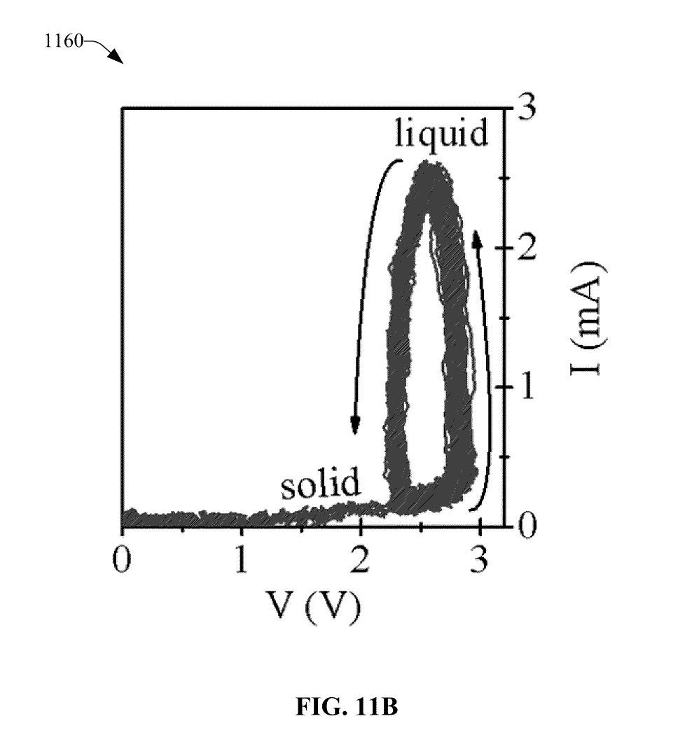

FIGS. 11A-11B illustrate (i) current-time (I-t) and voltage-time (V-t) characteristics and (b) current-voltage (I-V) characteristics, respectively, of an exemplary device in accordance with aspects of the subject disclosure. The exemplary device includes a switching element embodied in a SOI two-terminal nanostructure (see, e.g., device 240). In addition, the exemplary device includes a load resistor R_{L} with resistance of about 5.7 kΩ, and a capacitor C_{P} with a capacitance of about 150 pF. Such nanostructure is shaped as a nanowire having a length of about 100 nm, a width of about 680 nm, and a thickness of about 55 nm. Resistance of the nanowire is about 15 kΩ. Panel 1120 illustrates applied voltage pulse, which has an amplitude of about 6 V and a duration of about 35 μs, and voltage (V_{wire}) across the nanowire in response to at least the applied voltage pulse; V_{wire} presents oscillations with a frequency of about 2.37 MHz; see panel 1140. Likewise, current that circulates across the nanowire also oscillates at the same or substantially the same frequency of about 2.37 MHz. Current-voltage (I-V) characteristics of the exemplary device is illustrated in panel 1160 in FIG. 11B.

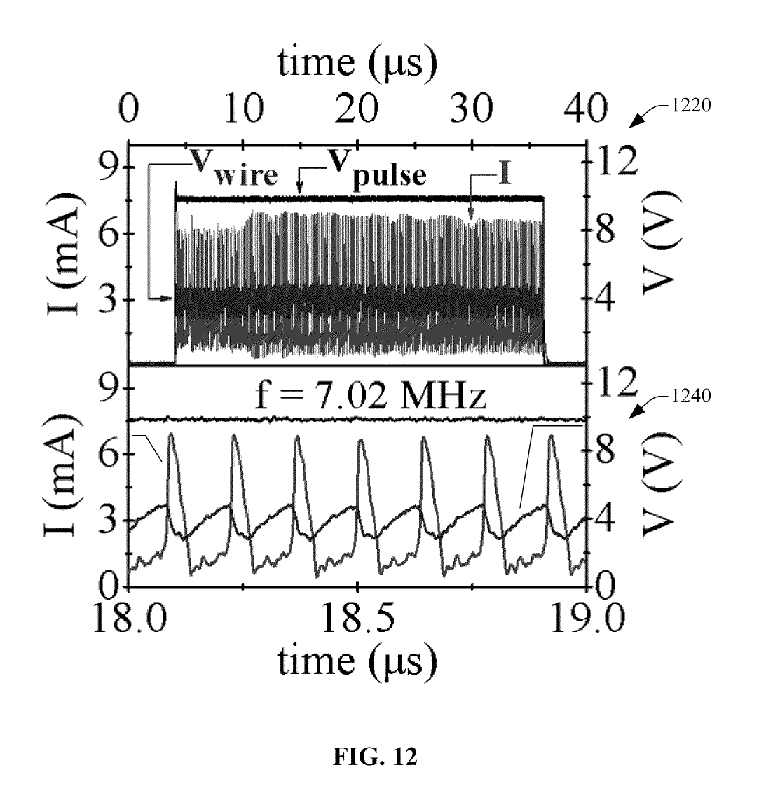

FIG. 12 illustrates current-time (I-t) and voltage-time (V-t) characteristics of another exemplary device in accordance with aspects of the subject disclosure. Such exemplary device also includes a switching element embodied in a SOI two-terminal nanostructure (see, e.g., device 240). The exemplary device also includes a load resistor R_{L} with resistance of about 2.6 kΩ and a capacitor C_{P} with a capacitance of about 30 pF. Such nanostructure is shaped as a nanowire having a length of about 60 nm, a width of about 700 nm, and a thickness of about 55 nm. Resistance R_{W} of the nanowire is about 6.5 kΩ. Amplitude of a voltage pulse applied to the exemplary is about 10 V and its duration is about 35 μs. Current that circulates through the nanowire (I_{wire}, represented by I inside panel 1220) in the switching element oscillates at a frequency of about 7.02 MHz. Likewise, voltage across the nanowire (V_{wire}) also oscillates at the same or substantially the same frequency. It should be appreciated that capacitance of capacitor C_{P} in the exemplary device that yields the data in FIG. 12 is smaller than that in the exemplary device that yields data in FIGS. 11A-11B. Capacitance of 30 pF is accomplished by floating one or more shields of coaxial cables employed in example system 300, in order to cause the one or more shields not to act as capacitors.

Switching devices that yield data in FIGS. 11A-11B and FIG. 12 can operate at voltages lower than those voltages applied to larger switching devices; see, for example, data shown in diagram 400. Capacitances of capacitor C_{P} in such switching devices is less than such capacitance in other switching devices in accordance with aspects described herein.

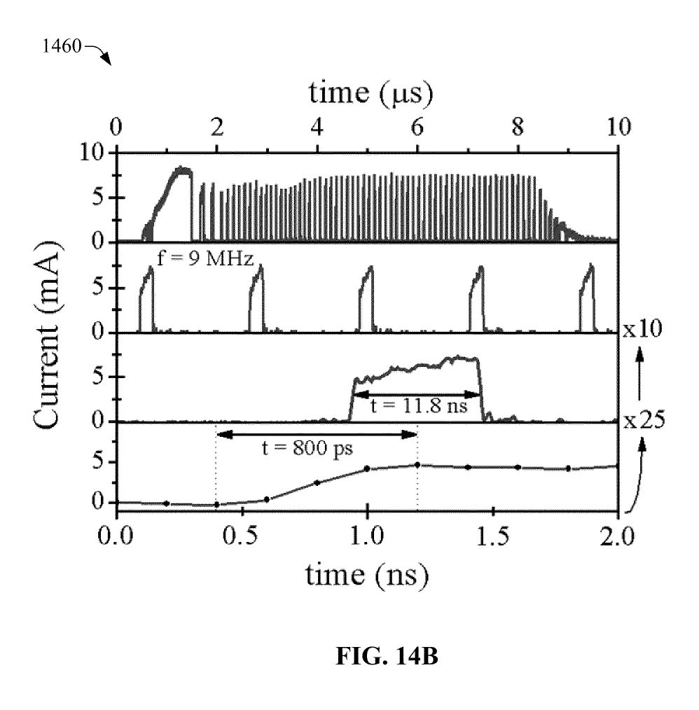

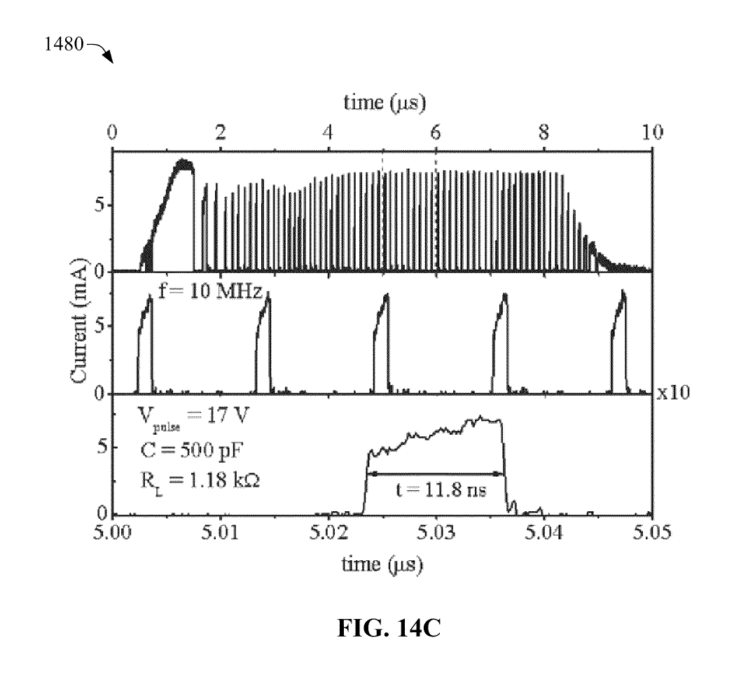

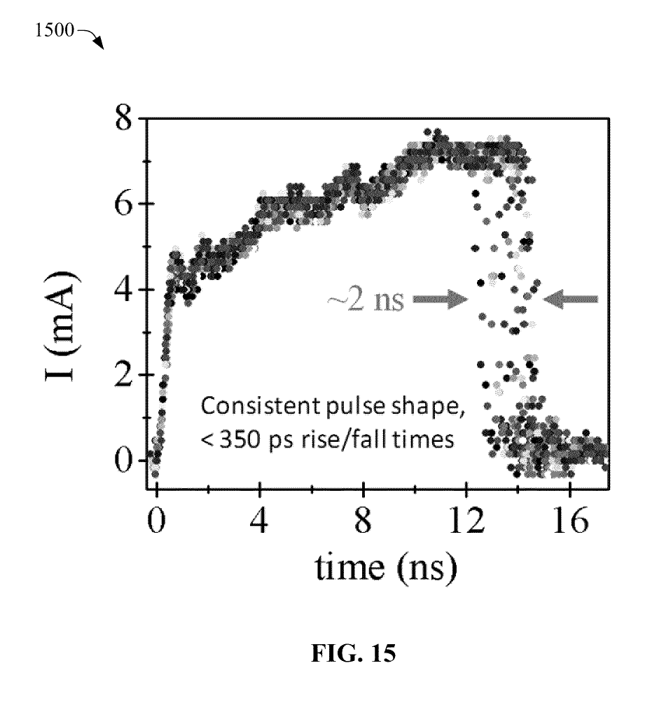

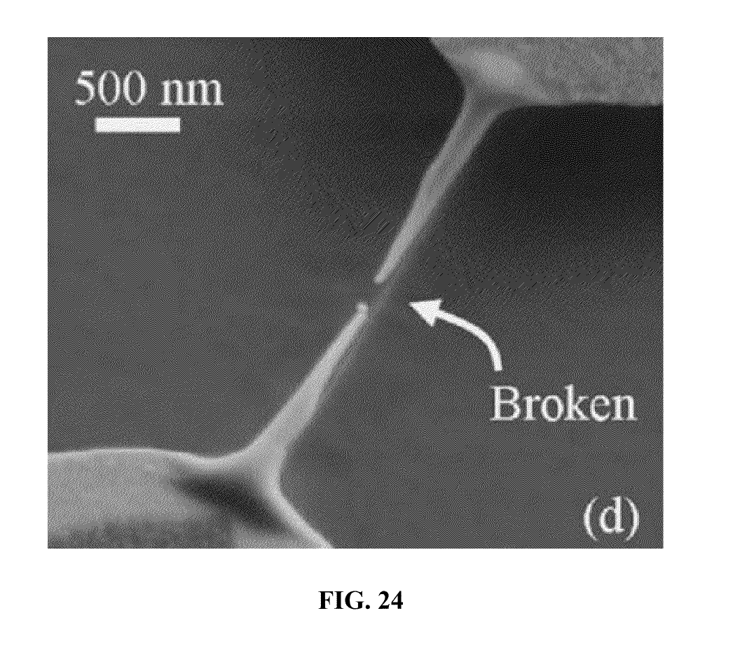

In certain embodiments, mechanical integrity of the wire that embodies switching element 110 is temporarily compromised (e.g., wire breaks; see FIG. 24 for example), with a first portion of the wire rapidly and repeatedly disconnecting and connecting from a second portion of the wire. Without wishing to be bound by theory or modeling, it is believed that such fluctuating integrity of the wire can lead to a second type of phase-change oscillators, with such oscillators having an oscillation frequency which can be about an order of magnitude higher that the oscillation frequency of a phase-change oscillator that preserves integrity of the wire, or more generally, the switching element. As illustrated hereinafter, switching devices that generate oscillating signal (current or voltage) based on loss and recovery of mechanical integrity due to solid-liquid phase switching, or phase change, can generate signal oscillation with various aspects comprising: high frequency or high repetition rate; consistent pulse profile (or shape) from a first break-heal event to a second break-heal event; ON/OFF transitions in output current ranging from zero (e.g., 0 mA) or substantially zero (e.g., about 0 mA) current to a substantive finite output current (e.g., about 10 mA) (see, e.g., FIGS. 14A-14C and FIG. 15); and ultra-fast rise time (e.g., less than about 350 ps) and ultra-fast fall time (e.g., less than about 350 ps) for such ON/OFF transitions (see, e.g., FIG. 15).

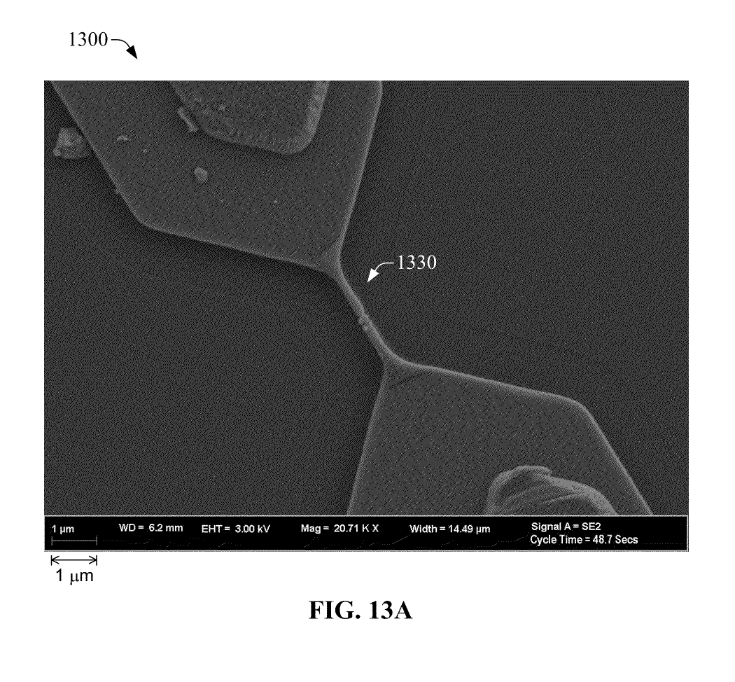

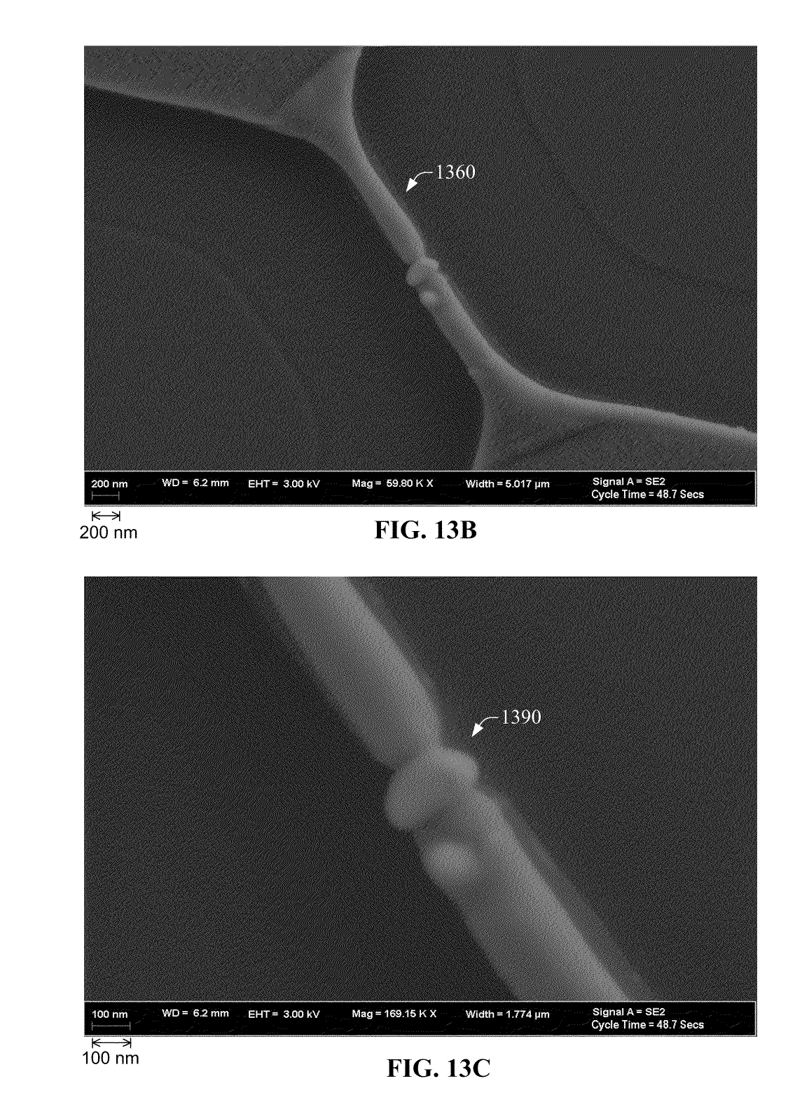

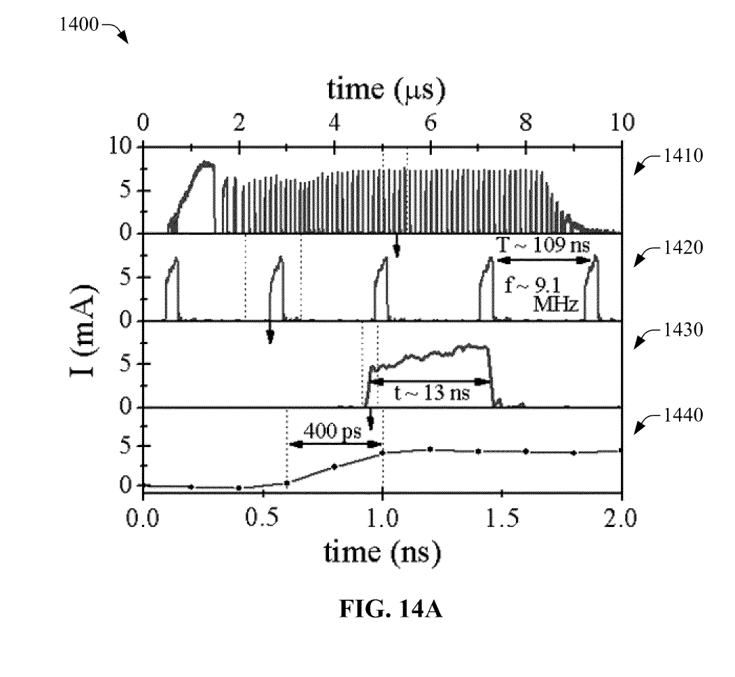

In an embodiment, a wire that embodies a switching element that operates based on breakage and reconnection of at least one portion of wire can be achieved, at least in part, by forming a structural constriction in such wire. In certain embodiments, the structural constriction can be formed by annealing an as-fabricated wire of a semiconducting material. In additional or alternative embodiments, the structural constriction can be fabricated (e.g., formed controllably) utilizing various semiconductor processing techniques, such as photolithography. Such structural constriction in the wire can drive the breakage: In an aspect, for a wire of a semiconducting material that shrinks upon melting (e.g., silicon), the wire can become disjointed at the structural constriction as a result of a smaller volume of the wire. In another aspect, as the wire re-solidifies and the volume of the wires increases (e.g., 5% volumetric increase), a disjointed part of the wire can reconnect. FIGS. 13A-13C illustrates an example wire with a structural constriction that can drive oscillations based on breakage of the wire.

FIG. 14A illustrates a diagram 1400 of I-t characteristics of an exemplary device (e.g., device 100) that comprises a exemplary wire that has a structural constriction in accordance with aspects of the subject disclosure. In an aspect, such exemplary wire is a non-passivated, partially suspended wire of a doped elemental semiconductor material. As illustrated in top panel 1410 of diagram 1400, and in a time scale spanning several microseconds, when the wire is not broken, spikes of current with rise/fall times ≦350 ps (times that in certain embodiments may be limited by performance of oscilloscope 310) and width of about 13 ns are generated as a result of biasing the exemplary device in accordance with aspects described supra. As illustrated in panel 1420, and observable in a shorter time scale, there is no current when the wire is broken, and the frequency of these “breakage” oscillations is about 9.1 MHz.

In the exemplary device that yields data presented in diagram 1400, pulses (e.g., finite time-domain regions of finite current I_{wire}) generated between about 4 μs and about 8 μs appear to be consistent. Similar features as those shown in FIG. 14A are observable in FIG. 14B. In an aspect, in panel 1460 in FIG. 14B, width of a current pulse when the wire reconnects is shorter than in the exemplary device for which data is shown in FIG. 14A.

FIG. 14C presents diagram 1480 of I-t curves for on/off current oscillations for an exemplary device in which the switching element (e.g., 110) is embodied in a wire of a semiconducting material that breaks and heals, or connects and disconnects) in response to a bias voltage as described herein. In an aspect, the wire is a suspended Si wire with a length of about 2.5 μm. Without wishing to be bound by theory or modeling, such wire is expected to be disconnecting as a result of melting and reconnecting after re-solidification. The time scales of the bottom two panels are shorter—such scales enable zooming into the region between dashed lines). In an aspect, generated pulse duration is 11.8 ns, rise and fall times are less than 1 ns each.

In general, ON/OFF oscillations arising from breakage or healing of a wire of semiconducting material with negative TCR and with negative thermal volumetric expansion coefficient can have oscillation frequencies on the order of 10 MHz with pulse widths of about 12 ns. In addition, rise and fall times can be lesser than about 1 ns. For Si wires, it should be appreciated that liquid silicon has higher density, hence a Si wire can shrink as it melts and expand when it re-solidifies, as noted hereinbefore. Without wishing to be bound by theory or modeling, such breakage and “healing” is believed to provide the sudden drops in current as wires melt and break, and sudden increases in current as wires re-solidify and make contact again, or heal.

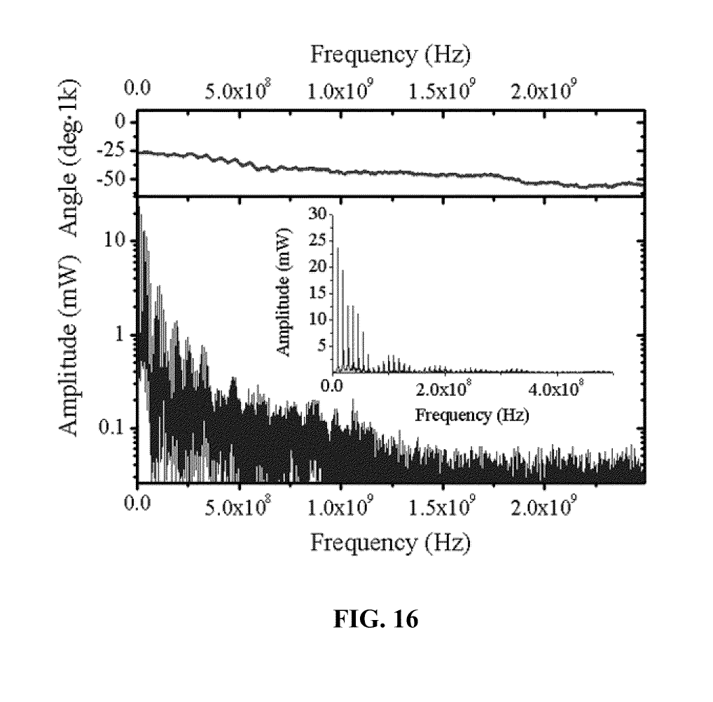

FIG. 15 illustrates a detail of 30 pulses extracted from a time-domain region that presents the most stability with respect to pulse generation; namely, the region in FIGS. 14A-14C between about 4 μs and about 8 μs. Such pulses are aligned by their rising edge for analysis purposes. Such analysis yields the following information. Rise and fall time of such pulses is less than 350 ps and limited by measurement instrument (e.g., oscilloscope 310); pulse width is about (13.48±0.65) ns; period of pulses is about (109.70±0.69 ns); and frequency is about (9.19±0.06) MHz. Analysis of pulses in the foregoing stable time-domain region can include fast Fourier transform (FFT) analysis. Results of FFT analysis are shown in FIG. 16.

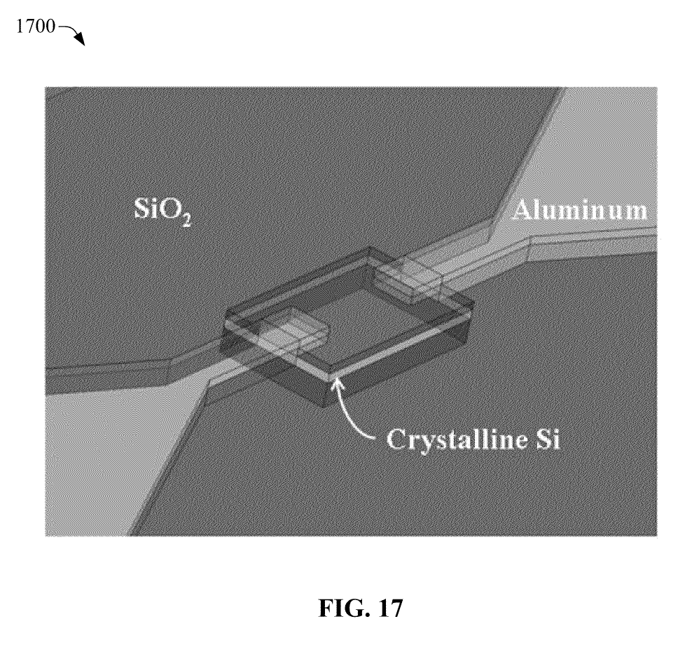

Enhancement of oscillation frequencies and enhanced stability can be achieved by controlled optimization of the scaling of the volume of the semiconducting material (e.g., silicon), capacitance of capacitor C_{P} included in devices disclosed herein, and adjustment or optimization of geometry of the wire of semiconducting material (e.g., silicon). In an aspect, simulation of model devices can be performed to develop insight into design aspects of the subject disclosure. Simulations are based on solving heat transfer equations coupled with electric conduction equations that can simulate Joule heating in a switching element. Simulation also account for coupling of a modeled switching element to a capacitor and a resistor, and stressing a resulting switching device with a bias voltage. FIG. 17 illustrates a model of a switching element (e.g., 110) in accordance with aspects of the subject disclosure. The wire is modeled as a wire on top of silicon dioxide, with the wire being a slab of crystalline silicon. Such slab has a width of 700 nm; the width determined in the direction normal to the metal-metal direction. The slab of crystalline silicon is covered with a passivation layer comprised of silicon dioxide and of a thickness of 50 nm. In addition, a layer of 145 nm of silicon dioxide resides underneath the slab of crystalline silicon. Metal-to-metal distance is 700 nm, and the total length of the device is 1.2 μm.

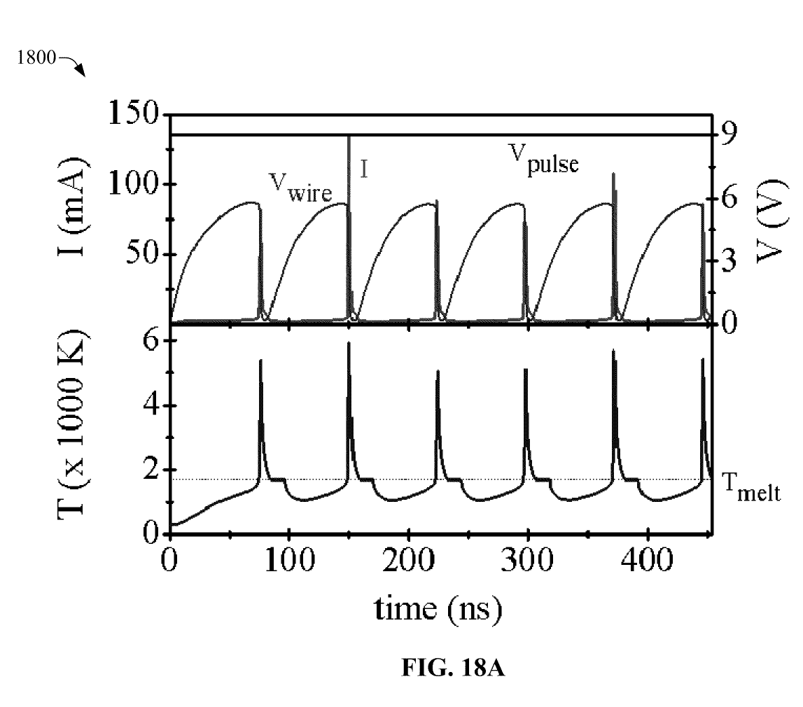

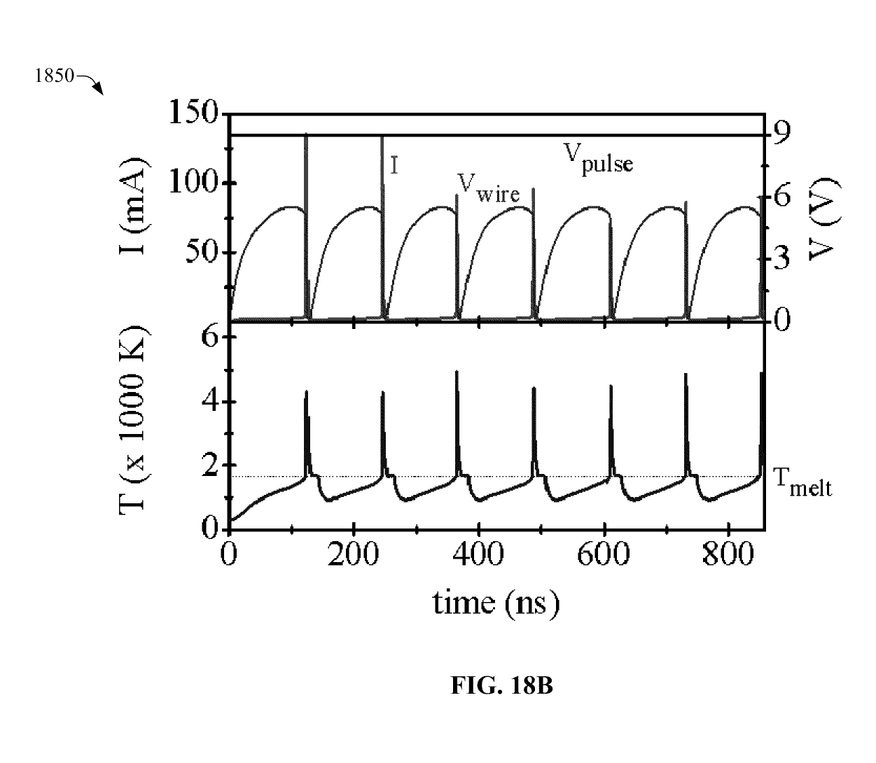

FIGS. 18A-18B illustrate, respectively, diagrams 1800 and 1850 conveying results of phase-change oscillations in the model switching element described hereinbefore. In diagram 1800, additional functional elements that are part of a switching device (e.g., device 100) are considered as follows. C_{P} is considered to be equal to 30 pF and R_{L} is considered to be equal to 1 kΩ. Top panel illustrates V-t and I-t characteristics of the wire: voltage across the wire as a function of time, current that circulates through the wire as a function of time, and bias voltage (Vₚᵤₗₛₑ). Bottom panel presents results for temperature of the wire in response to application of the bias voltage. Melting temperature of silicon is indicated in the drawing as Tₘₑₗₜ. Predicted oscillation frequency is 13.67 MHz. Diagram 1850 presents results for similar properties to those presented in diagram 1800. Switching device simulated comprises the model switching element described supra, a capacitor C_{P} with capacitance equal to 30 pF, and a load resistor R_{L} with resistance equal to 1.25 kΩ. Results of simulations are similar, yet not identical, to those obtained for the device simulated in connection with diagram 1800. Predicted oscillation frequency is 8.79 MHz.

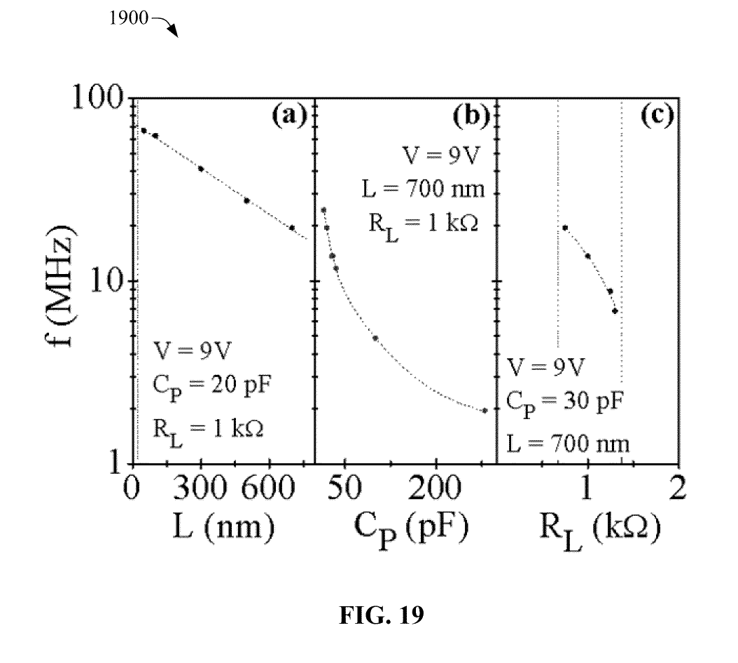

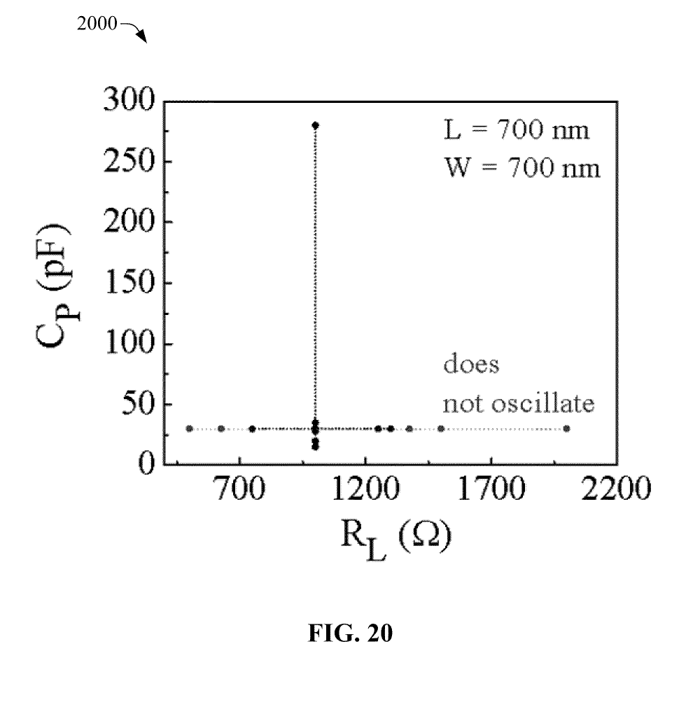

FIG. 19 is a diagram 1900 that summarizes trends of predicted oscillation frequency as a function of length of the wire that embodies the switching element, capacitance of capacitor C_{P}, and resistance of resistor R_{L}. In a first scenario, for a bias voltage of amplitude equal to 9 V, C_{P}=20 pF, and R_{L}=1 kΩ, predicted oscillation frequency decreases with increasing length of the wire. In a second scenario, for a bias voltage of amplitude of 9 V, R_{L}=1 kΩ, and length equal to 700 nm, predicted oscillation frequency decreases with increasing C_{P}. In a third scenario, for bias voltage of amplitude of 9 V. In addition, FIG. 20 presents a diagram 2000 representing a resistance-capacitance map that summarizes results of predictions associated of phase-change oscillators for the model wire of FIG. 17 with a length of 700 nm and a width of 700 nm.

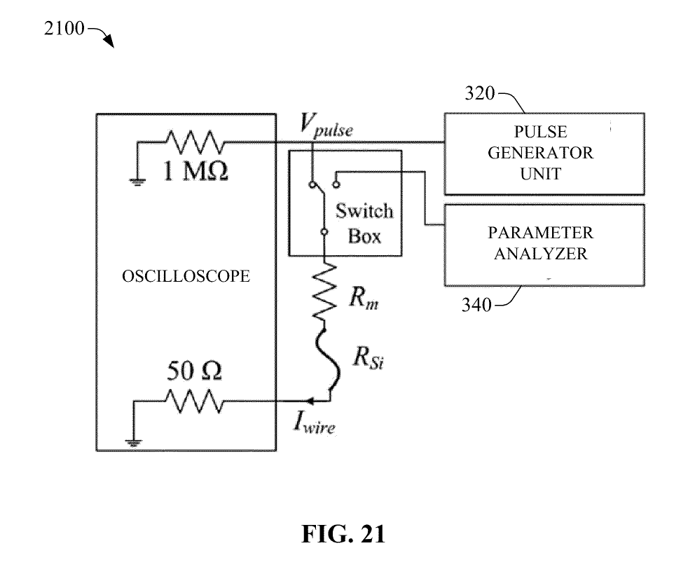

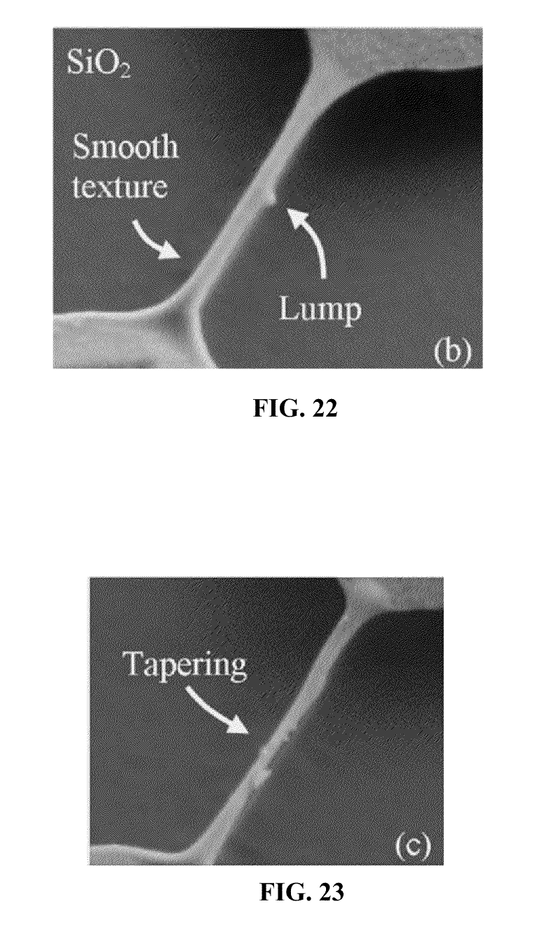

FIG. 21 illustrates an exemplary system 2100 that can be employed to treat wires of semiconducting materials that can embody a switching element 110. It should be appreciated that the exemplary device that is probed is a variation of exemplary device 100 in the capacitor C_{P} is not part of the device employed to treat the wire in accordance with aspects of the subject disclosure. In an aspect, exemplary system 2100 enables measurement of current-voltage (I-V) characteristics using the parameter analyzer 340 before and after a voltage pulse, or bias voltage is applied. As described hereinbefore, pulse amplitude (Vₚᵤₗₛₑ) and current through the wire (I_{wire}) are monitored using the oscilloscope during the pulse. As-fabricated suspended n-type wires are wide and thin with uniform nanocrystalline texture (see, e.g., FIG. 2A). Wires stressed with large amplitude (40 V), short duration (e.g., 1 μs) voltage pulses acquire smooth surfaces, cylindrical shape, and a lump in the middle (FIG. 22). In addition to the lump, a defect such as grain boundary or other type of crystal defect can be present. In certain embodiments, longer duration pulses (e.g., 2 μs, 5 μs) can lead to tapering (see, e.g., FIG. 23), or plastic deformation and breaking of the wires. It should be appreciated that breakage results from applying a pulse amplitude of 40 V for 5 μs.

In an aspect, conductance of a wires fabricated in accordance with aspects herein can be enhanced after the voltage pulse for those wires that do not break as a result of application of the bias voltage. FIGS. 22-23 illustrate a 2.5 μm long suspended n-type wires of similar widths with total pre-pulse resistance of about 47.8 kΩ and 52.4 kΩ, respectively. Total resistance of (R_{wire}) consists of the wire (e.g., about 10 kΩ) and contact-pad resistances (e.g., about 40 kΩ). In response to application of the pulse, in an embodiment, total resistance of the wires in FIGS. 22-23 are measured as 19.6 kΩ and 20.3 kΩ, respectively. It should be appreciated that such values are smaller than the pre-pulse contact-pad resistance. Without wishing to be bound by theory or modeling, low post-pulse resistance is generally attributed to conductance enhancement in both the wires and the contact regions, even though the changes in the contact regions are not observable under scanning electron microscope (SEM) (see, e.g., FIG. 22). The contact-pad resistance (R_{C}) in such wires can depend on the probe placement on the contact regions.

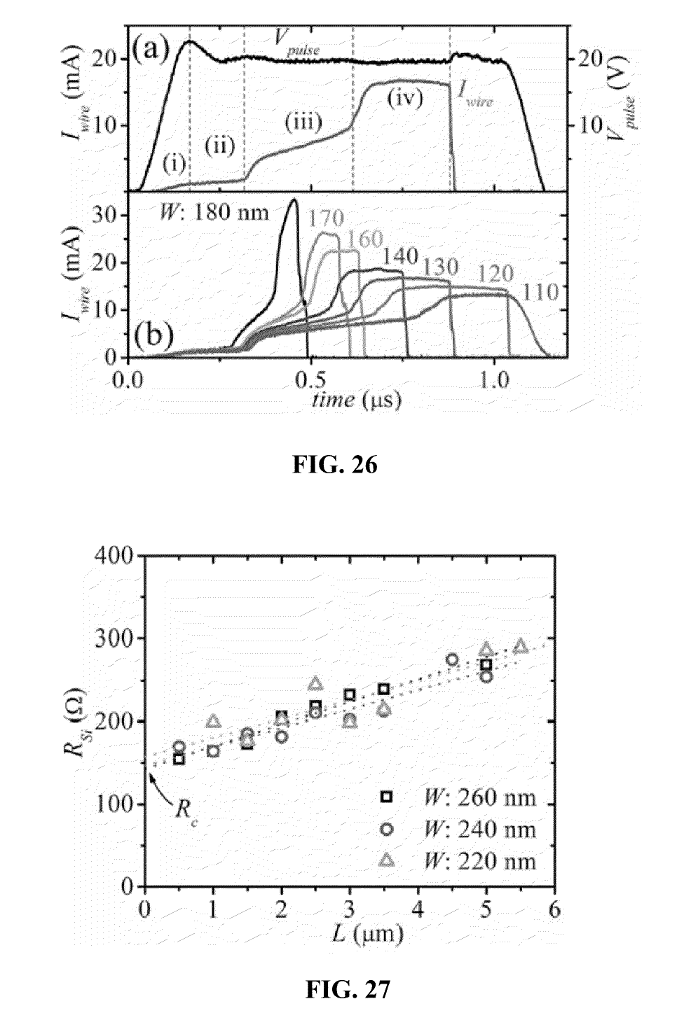

Example system 2100 enables systematic measurements of current-voltage characteristics before, during, and after application of a voltage pulse or voltage bias. In an embodiment, such types of I-V characteristics measurements are performed on p-type silicon wires, resting on oxide, with metal (Ti/Ni) contacts; such wires are illustrated in FIG. 25. Current-voltage (I-V) measurements before and after the voltage pulse are performed using low voltage dc sweeps (e.g., from 0 V to 2 V) in order to prevent any resistance changes due to self-heating during the measurement (FIG. 23, inset). In an aspect, wire illustrated in FIG. 3 is a 5.5 μm long, 110 nm wide p-type wire after a voltage pulse of amplitude of about 20 V and duration of about 1 μs pulse has been applied. Current-time characteristics of such wire is shown in FIG. 26, panel (b); as indicated hereinbefore width of the wire is about 110 nm. Is illustrated in the inset of FIG. 25, resistivity of the wire decreases by a factor of 4 after treatment (or annealing with a voltage pulse or bias voltage.

FIG. 26, panel (a), illustrates current-time (I_{wire}-time) and voltage-time (Vₚᵤₗₛₑ-time) characteristics of p-type wire during single, 1 μs voltage pulses. Measurements are performed through oscilloscope 310. Current-time and voltage-time characteristics present significant nonlinear changes in the current level during application of the voltage pulse or voltage bias. For example, region (i) is the initial transient period. Without wishing to be bound by theory or modeling, the increase in current in region (ii) is expected due to the negative temperature coefficient of resistivity of the as-fabricated material (nc-Si). In an aspect, the I-t and V-t characteristics present stepwise and significant changes in current in regions (iii) and (iv). In another aspect, a plateau in region (iv) is observed. Total resistance (Vₚᵤₗₛₑ/I_{wire}) corresponding to the maximum current in region (iv) of FIG. 24, panel (a), is about 1.18 kΩ, whereas the metal line resistance (Rₘ) for the wire and probes is about 840Ω. Hence the silicon resistance (R_{Si}), including Si contact pad (R_{c}) and wire resistances, is about 340Ω during the pulse (e.g., 1.6% of its initial value).

In an aspect, R_{Si} in region (iv) (see, e.g., FIG. 24, panel (b)) can be extracted for wires of various dimensions, accounting for Rₘ. Without wishing to be bound by theory or modeling, if the Si wires are assumed to be linear resistors with uniform cross sections along the wire, R_{Si} can be written as

$${R}_{Si} = {R}_{c} + \frac{ρ}{Wt} L , \qquad Eq . ( 1 )$$

where R_{c} is the silicon contact-pad resistance and ρ is the resistivity of Si wires. Effective wire widths (W) can deviate from the design widths (W_{d}) by ΔW (e.g., about 250 nm in certain embodiments) due to the lithography process. Therefore, in an aspect, ΔW, and thus W, can be extracted from systematic resistance measurements on the wires prior to application of the voltage pulse or the voltage bias. Slopes of R_{Si} versus L lines

$$( α = \frac{ρ}{Wt} ) ,$$

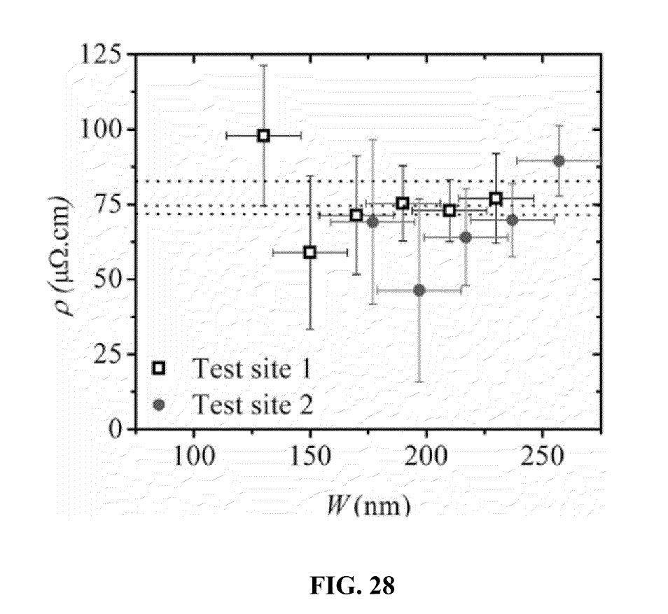

hence ρ, can be obtained from linear regression, as illustrated in FIG. 27. As an illustration, FIG. 28 presents ρ obtained from two test sites for various W with estimated errors. In an aspect, the weighted average of ρ is calculated as (75.0±4.6) μΩcm without accounting for 5% volume contraction of wires in liquid phase, as mentioned supra. Errors in ρ (see, e.g., FIG. 26) can be due to the errors in film thickness measurements and regression errors in α and ΔW. Dashed lines in FIG. 28 indicate previously known liquid silicon resistivity values of 83 μΩcm, 75.2±0.6 μΩcm, and 72 μΩcm, extracted using bulk silicon with large-scale, high-temperature setups. Close agreement between extracted p and the liquid silicon resistivity values indicates that Si wires melt due to application of voltage pulse or bias voltage, as described supra (see, e.g., FIG. 26, panel (b), region (iv)).

In addition, without wishing to be bound by theory or modeling, small R_{c} values (see, e.g., FIG. 27) of the wires during application of the pulse suggest that the silicon contact pads are also molten during region (iv) of application of voltage pulse. Further, and without intent to be bound by theory or modeling, observation of re-solidified filaments between the metal contacts and the wire (see, FIG. 23) supports support such argument. Thus, without wishing to be bound by theory or modeling, changes in current in region (iii) and region (iv) in FIG. 26, panel (a), can be attributed to melting of the wire and filament formations, respectively, resulting in a complete molten silicon path between metal contacts. It should be appreciated that such melting can serve as a treatment, or annealing, of the wires of semiconducting materials that can be employed in on/off connection oscillators described hereinbefore. Without wishing to be bound by theory or simulation, wires treated in accordance with aspects described herein are expected to melt prior to filament formation due to the thermal boundary conditions. Furthermore, in wires where the applied voltage pulse does not lead to the last step in I_{wire}-time characteristics [region (iv) in FIG. 26, panel (a)], SEM does not provide data supporting filamentation, or filament formation. The stability in current in region (iv) once a liquid path is formed between the metal contacts is due to the relative insensitivity of liquid silicon resistivity to temperature. Such feature enables extraction of liquid silicon resistivity via measurement performed with example system 2100.

Conventional experiments on amorphous silicon wires indicate that polycrystalline grains can grow longer for narrower wires and tend to form single crystal domains along wires with widths less than 250 nm. Accordingly, without wishing to be bound by theory or modeling, solidification of the suspended wires upon termination of voltage pulse (see, e.g., FIG. 22) is expected to yield two continuous grains with low defect density if the wires are narrower than the thermodynamically favored grain size. Strong thermal gradient along the suspended wires, due to low heat loss to the substrate, would suppress nucleation and consequently grain boundaries within these wires. As the two solid fronts meet in the middle, some portion of the molten silicon cannot fit between re-solidified regions due to the higher density of liquid silicon. Excess silicon is ejected and forms a lump upon re-solidification (FIG. 22).

In an aspect, compared the as-fabricated nanocrystalline texture of wires of semiconducting materials fabricated in accordance with aspects described herein, smooth surfaces for such wires can be obtained after application of high amplitude, short-duration voltage pulses to such wires. In an aspect, current through such wires presents nonlinear changes during the application of the pulse; exemplary system 2100 enables such observation. Minimum resistivity of the wires, extracted from I-V characteristics obtained during application of voltage pulse, matches available resistivity values for liquid silicon. In certain embodiments, the post-pulse resistivity of the wires can be typically about four times smaller than their as-fabricated values. Accordingly, the subject disclosure provides a method for treating microscopic wires of semiconducting materials and achieving improved conductance for such wires. The method comprises melting as-fabricated wires through self-heating during application of a voltage pulse. In response to termination of the applied voltage pulse, the molten wires crystallize. In an aspect, re-solidification of the wires can start from the two ends of the wire and the re-solidified regions meet in the middle. Two crystalline domains are expected to form in presence of a strong lateral thermal gradient if the wire is narrower than the thermodynamically favored grain size. These results indicate that crystallization of patterned micro/nanostructures through voltage pulse induced self-heating can be a viable crystallization approach, compatible with a variety of substrates. It should be appreciated that generation of crystalline domains or material segregation can serve as nucleation sites for defect formation in scenarios in which a wire with crystalline domains is employed to form a phase-change oscillator. In addition, the subject disclosure provides an approach for calculation of resistivity during application of short-duration voltage pulses is a submicrometer scale, low-cost alternative for extraction of resistivity of molten materials.

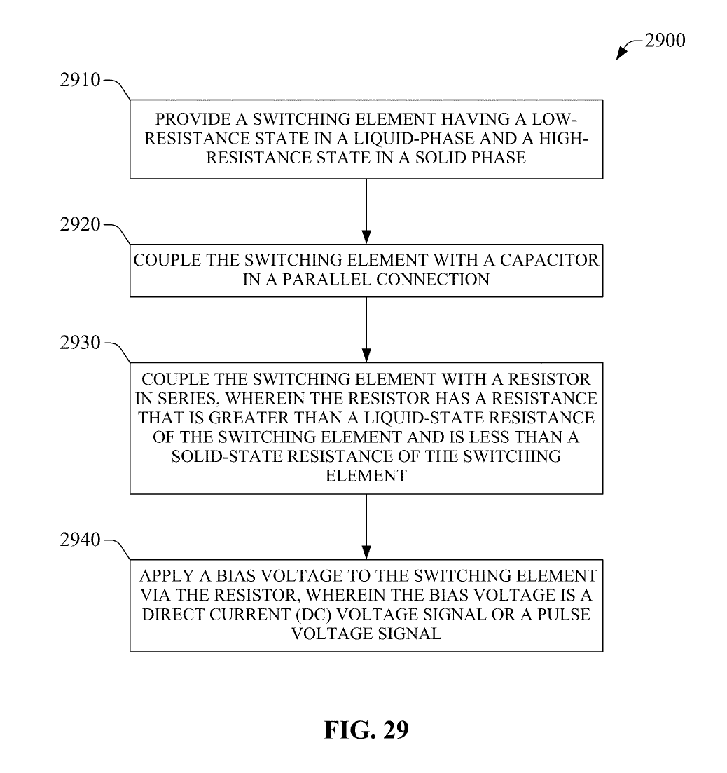

In view of the various aspects described hereinbefore, an exemplary method 2900 that can be implemented in accordance with the disclosed subject matter can be better appreciated with reference to the flowchart in FIG. 29. For purposes of simplicity of explanation, the exemplary method 2900 disclosed herein is presented and described as a series of acts or steps; however, it is to be understood and appreciated that the various processes or methods described and claimed in the subject disclosure are not limited by the order of acts or steps, as some acts or steps may occur in different orders and/or concurrently with other acts from that shown and described herein. Moreover, not all illustrated acts or steps may be required to implement a process or method in accordance with the subject disclosure. Furthermore, two or more of the disclosed methods or processes can be implemented in combination with each other, to accomplish one or more features or advantages herein described.

FIG. 29 is a flowchart of an exemplary method 2900 for generating signal based on solid-liquid phase switching according to aspects of the subject disclosure. At act 2910, a switching element having a low-resistance state in a liquid-phase and a high-resistance state in a solid phase is provided. In an aspect, the switching element has a negative thermal coefficient of resistance (TCR). As described supra, the switching element can be a negative TCR in a portion of the range of temperatures from about room temperature to about melting temperature of the switching element or a portion thereof (e.g., a wire or a two-terminal structure of a semiconducting material). In certain embodiments, act 2910 (also referred to as the providing step) can comprise fabricating a miniaturized wire of a semiconducting material having a negative TCR, wherein such wire embodies the switching element (e.g., switching element 110). In additional or alternative embodiments, the fabricating (or fabricating step) can comprise fabricating the miniaturized wire as a structure coupled to at least two metal contact pads, wherein the structure is one of a suspended structure, a non-suspended structure, or a partially suspended structure. For certain structures (e.g., SOI structures) fabricating the structure comprises etching a wafer of an elemental semiconductor material on an insulator. In yet additional or further alternative embodiments, the fabricating (or fabricating step) can comprise depositing by chemical vapor deposition the miniaturized wire on a nanocrystalline semiconductor substrate, and passivating the miniaturized wire with an oxide material, wherein the oxide material is a semiconductor oxide, a metal oxide, or an actinide oxide. It should be appreciated that the fabricating (or fabricating step) can comprise producing various passivated and non-passivated structures that can be suspended or non-suspended.

At act 2920, the switching element is coupled with a capacitor in a parallel connection (see, e.g., FIG. 1). As described supra, the capacitor provides a non-zero capacitance that enables relaxation oscillations amongst the solid-phase and a liquid-phase. At act 2930, the switching element is coupled with a resistor in series (see, e.g., FIG. 1). In another aspect, the resistor has a resistance that is greater than a liquid-state resistance of the switching element and is less than a solid-state resistance of the switching element.

At act 2940, a bias voltage is applied to the switching element via the resistor, wherein the bias voltage is a direct current (DC) voltage signal or a pulse voltage signal. In an aspect, the pulse voltage signal generally has a finite amplitude and a finite duration (see, e.g., FIG. 11A or FIG. 12). Applying the bias voltage to the switching element also is referred to as stressing the switching element.

While the systems, devices, apparatuses, protocols, processes, and methods have been described in connection with exemplary embodiments and specific illustrations, it is not intended that the scope be limited to the particular embodiments set forth, as the embodiments herein are intended in all respects to be illustrative rather than restrictive.

Unless otherwise expressly stated, it is in no way intended that any protocol, procedure, process, or method set forth herein be construed as requiring that its acts or steps be performed in a specific order. Accordingly, in the subject specification, where description of a process or method does not actually recite an order to be followed by its acts or steps or it is not otherwise specifically recited in the claims or descriptions of the subject disclosure that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification or annexed drawings, or the like.

It will be apparent to those skilled in the art that various modifications and variations can be made in the subject disclosure without departing from the scope or spirit of the subject disclosure. Other embodiments of the subject disclosure will be apparent to those skilled in the art from consideration of the specification and practice of the subject disclosure as disclosed herein. It is intended that the specification and examples be considered as non-limiting illustrations only, with a true scope and spirit of the subject disclosure being indicated by the following claims.

What is claimed is:

1. An apparatus, comprising:
a capacitor;
a switching element coupled in parallel connection with the capacitor; the switching element having a low-resistance state in a liquid-phase and a high-resistance state in a solid phase, wherein the switching element has a negative thermal coefficient of resistance; and
a resistor coupled in series with the switching element and configured to supply a bias voltage to the switching element.

2. The apparatus of claim 1, wherein the switching element comprises a wire of a semiconducting material having negative thermal coefficient of resistance.

3. The apparatus of claim 2, wherein the switching element outputs an oscillating voltage having a frequency dependent at least on a capacitance of the capacitor and a contact resistance of a metal contact amongst the wire and a metal pad coupled to at least one of the resistor or the capacitor.

4. The apparatus device of claim 1, wherein a resistance of the resistor is less than a solid-phase resistance of the high-resistance state, and the resistance of the resistor is greater than a liquid-phase resistance in the low-resistance state.

5. The apparatus of claim 2, wherein the semiconducting material is one of an intrinsic semiconductor, an n-doped semiconductor, or a p-doped semiconductor.

6. The apparatus of claim 2, wherein the liquid-phase is a molten state of the wire and the solid-phase is a solid state of the wire.

7. The apparatus of claim 6, wherein the oscillating voltage originates at least in part from the wire alternating between the molten state and the solid state at the frequency of the oscillating voltage.

8. The apparatus of claim 6, wherein the switching element outputs an oscillating current having a frequency dependent on the rate of transition between a connected state and a disconnected state of the wire.

9. The apparatus of claim 8, wherein the frequency is at least 9 MHz.

10. The apparatus of claim 8, wherein the frequency is at least 0.8 MHz.

11. A device, comprising:
a miniaturized wire of a semiconducting material having a negative temperature coefficient of resistance and having a first resistance in a liquid state and a second resistance in a solid state, wherein the first resistance is less than a resistance of a resistor coupled to the wire, and the second resistance is greater than the resistance of the resistor; and
at least two contacts between the wire and at least two metal lines, wherein a contact of the at least two contacts is a metal.

12. The device of claim 11, wherein the wire is suspended amongst two of the at least two contacts.

13. The device of claim 11, wherein the wire is deposited on a semiconductor substrate.

14. The device of claim 11, wherein the wire is deposited on a substrate of a first oxide material and passivated with a second oxide material.

15. The device of claim 11, wherein the miniaturized wire has at least a first dimension that is less than about 5.5 μm and at least a second dimension that is less than about 700 nm, wherein the first dimension and the second dimension are both non-zero.

16. A method, comprising:
providing a switching element having a low-resistance state in a liquid-phase and a high-resistance state in a solid phase, wherein the switching element has a negative thermal coefficient of resistance (TCR);
coupling the switching element with a capacitor in a parallel connection; and
coupling the switching element with a resistor in series, wherein the resistor has a resistance that is greater than a liquid-state resistance of the switching element and is less than a solid-state resistance of the switching element.

17. The method of claim 16, wherein the providing step comprises fabricating a miniaturized wire of a semiconducting material having a negative TCR.

18. The method of claim 17, wherein the fabricating step comprises fabricating the miniaturized wire as a suspended structure coupled to at least two metal contact pads, wherein the structure is one of a suspended structure, a non-suspended structure, or a partially suspended structure.

19. The method of claim 17, wherein the fabricating comprises, depositing by chemical vapor deposition the miniaturized wire on a nanocrystalline semiconductor substrate, and
passivating the miniaturized wire with an oxide material, wherein the oxide material is a semiconductor oxide, a metal oxide, or an actinide oxide.

20. The method of claim 16, further comprising applying a bias voltage to the switching element via the resistor, wherein the bias voltage is a direct current (DC) voltage signal or a pulse voltage signal.
